(19) United States
(12) Patent Application Publication
(10) Pub. No.: US 2010/0279468 A1
(43) Pub. Date: Nov. 4, 2010

(54) LAMINATED FILM AND PROCESS FOR PRODUCING SEMICONDUCTOR DEVICE

(75) Inventors: Hironao OOTAKE, Osaka (JP); Katsuhiko KAMIYA, Osaka (JP)

Correspondence Address: SUGHRUE-265550, 2100 PENNSYLVANIA AVE. NW, WASHINGTON, DC, 20037-3213, US

(73) Assignee: NITTO DENKO CORPORATION, Osaka (JP)

(21) Appl. No.: 12/763,588

(22) Filed: Apr. 20, 2010

(30) Foreign Application Priority Data
Apr. 30, 2009 (JP) 2009-110576

(51) Int. Cl. H01L 21/50; B32B 7/12

(52) U.S. Cl. 438/113; 428/343; 428/355 AC; 438/118; 257/E21.499

(57) ABSTRACT

The present invention provides a laminated film which includes a pressure-sensitive adhesive sheet including a pressure-sensitive adhesive layer, and a die-adhering layer laminated on the pressure-sensitive adhesive layer of the pressure-sensitive adhesive sheet, the laminated film being for use in a production step of a semiconductor device, in which the pressure-sensitive adhesive layer of the pressure-sensitive adhesive sheet contains a water-supporting body, and the pressure-sensitive adhesive layer has a gel fraction of 90% by weight or more.

### FIELD OF THE INVENTION

The present invention relates to a laminated film and a process for producing a semiconductor device. More specifically, it relates to a laminated film as a pressure-sensitive adhesive sheet fitted with a die-adhering layer for use in the production of a semiconductor device and a process for producing a semiconductor device using the laminated film.

### BACKGROUND OF THE INVENTION

Hitherto, a semiconductor wafer (sometimes simply referred to as “wafer”) composed of silicon or gallium arsenide is mounted on a carrier such as a lead frame or a module substrate after a large wafer is cut into a small wafer (die). At the mounting, the wafer is adhered through an adhesive such as an epoxy resin. However, with the recent progress of miniaturization and thinning of the wafer, it becomes difficult to apply an appropriate amount of the adhesive to the small wafer without damaging the wafer.

With respect to the above-described problem, although there is a method of mounting a semiconductor chip after attaching a sheet-shaped die-adhering adhesive layer to a carrier in advance, an increase in step number and facility is indispensable since it is necessary to cut the die-adhering adhesive layer into the same size as the size of the semiconductor chip in advance.

Furthermore, there have been proposed various wafer-adhering pressure-sensitive adhesive sheets simultaneously having a fixing function at wafer cutting and a die-adhering function. That is, a semiconductor chip fitted with a die-adhering layer can be obtained by providing a die-adhering layer on a pressure-sensitive adhesive layer (wafer-fixing pressure-sensitive adhesive layer) of a dicing tape that is a wafer-fixing pressure-sensitive sheet, placing a semiconductor wafer thereon, cutting the wafer into small pieces, and subsequently picking up semiconductor chips through peeling them between the pressure-sensitive adhesive layer and the die-adhering layer.

In the above-described method, so-called direct bonding is enabled and production efficiency of the semiconductor chip can be improved to a large extent but there are required such conflicting functions that a wafer should be fixed so as not to generate chip fly in a cutting step and the chip should be easily peeled off between the pressure-sensitive adhesive layer and the die-adhering layer so as not to induce picking-up failure in a picking-up step.

With respect to the problem, there have been proposed various pressure-sensitive adhesive sheets having a mechanism of changing pressure-sensitive adhesive force between the wafer-fixing pressure-sensitive adhesive layer and the die-adhering layer by heat, radiation ray irradiation, or the like.

For example, there is disclosed a film wherein a dicing tape having a pressure-sensitive adhesive layer where a radiation ray-curable additive is added to a usual pressure-sensitive adhesive is laminated with a die-adhering layer in an integrated fashion (see, e.g., Patent Document 1). In the case where this laminated film is used, after diced, the wafer is irradiated with a radiation ray to cure the pressure-sensitive adhesive of the dicing tape and lower the pressure-sensitive adhesiveness and then a semiconductor chip can be peeled off at the interface between the die-adhering layer and the dicing tape in a perpendicular direction and thus the wafer fitted with the die-adhering layer can be picked up. However, in the method using an ultraviolet ray-curable pressure-sensitive adhesive layer as the pressure-sensitive adhesive layer, there is a problem that the pressure-sensitive adhesive force of the ultraviolet ray-curable resin does not completely disappear and thus a picking-up success rate is low.

Moreover, although there is a method of laminating a die-adhering layer on a pressure-sensitive adhesive layer containing heat-expandable microspheres of a heat-peelable pressure-sensitive adhesive sheet (see, e.g., Patent Document 2), there is a case where fouling occurs on the peeled surface of the die-adhering layer through cohesive failure of the pressure-sensitive adhesive component of the heat-peelable pressure-sensitive adhesive sheet. The fouling of the die-adhering layer may cause insufficient adhesion to the lead frame, module substrate, or the like or generation of voids at the interface between the die-adhering layer and the lead frame, module substrate, or the like during a reflow step after the semiconductor chip is mounted.

Patent Document 1: JP-A-02-248064

Patent Document 2: JP-A-03-268345

### SUMMARY OF THE INVENTION

Accordingly, an object of the invention is to provide a laminated film which, as a laminated film having a constitution that a die-adhering layer and a pressure-sensitive adhesive sheet are laminated, enables peeling of a semiconductor chip fitted with the die-adhering layer from the pressure-sensitive adhesive sheet with ease and with suppressing or preventing fouling of the die-adhering layer in a picking-up step as well as a process for producing a semiconductor device using the laminated film.

As a result of extensive studies in order to solve the above-described problems, the inventors of the present application have found that, when a water-supporting body capable of generating water vapor by heating is used and a gel fraction of the pressure-sensitive adhesive layer is controlled to a prescribed value, a semiconductor chip fitted with a die-adhering layer can be peeled from a pressure-sensitive adhesive sheet with ease and with suppressing or preventing fouling of the die-adhering layer in a picking-up step. Thus, the inventors have accomplished the invention.

Namely, the present invention provides a laminated film which includes a pressure-sensitive adhesive sheet including a pressure-sensitive adhesive layer, and a die-adhering layer laminated on the pressure-sensitive adhesive layer of the pressure-sensitive adhesive sheet, the laminated film being for use in a production step of a semiconductor device, in which the pressure-sensitive adhesive layer of the pressure-sensitive adhesive sheet contains a water-supporting body, and the pressure-sensitive adhesive layer has a gel fraction of 90% by weight or more.

As above, since the laminated film of the invention (sometimes referred to as a “pressure-sensitive adhesive sheet fitted with (the) die-adhering layer”) has a constitution that a die-adhering layer is laminated on a pressure-sensitive adhesive layer of a pressure-sensitive adhesive sheet and has constitutions or characteristics of the following (1) and (2), after the cut-processing (after dicing) of a semiconductor wafer, water contained in the water-supporting body in the pressure-sensitive adhesive layer (water-supporting body-containing pressure-sensitive adhesive layer) of the pressure-sensitive adhesive sheet spouts as water vapor and the like from the surface of the pressure-sensitive adhesive layer and presses the contact surface with the die-adhering layer, so that peeling can be easily achieved at the interface between the pressure-sensitive adhesive layer of the pressure-sensitive adhesive sheet and the die-adhering layer and thus it is possible to effectively obtain a semiconductor chip fitted with the die-adhering layer. Furthermore, since the die-adhering layer is peeled from the pressure-sensitive adhesive layer of the pressure-sensitive adhesive sheet by the pressure of the water vapor generated from the water-supporting body in the pressure-sensitive adhesive layer, the die-adhering layer can be peeled from the pressure-sensitive adhesive layer without occurrence of cohesive failure of pressure-sensitive adhesive components of the pressure-sensitive adhesive layer and hence it is possible to effectively suppress or prevent fouling of the die-adhering layer due to the remaining of the pressure-sensitive adhesive components at peeling.

(1) The pressure-sensitive adhesive layer of the pressure-sensitive adhesive sheet contains a water-supporting body.

(2) A gel fraction of the pressure-sensitive adhesive layer (water-supporting body-containing pressure-sensitive adhesive layer) is 90% by weight or more.

According to the invention, it is preferable that the pressure-sensitive adhesive layer (water-supporting body-containing pressure-sensitive adhesive layer) is a pressure-sensitive adhesive layer containing as a base polymer an acrylic polymer composed of an acrylic acid alkyl ester represented by CH₂═CHCOOR (where R is an alkyl group having 6 to 10 carbon atoms) as a main monomer component, and the ratio of the acrylic acid alkyl ester represented by the above formula is 50 to 99% by mol based on the total amount of monomer components.

Furthermore, according to the invention, a support in the water-supporting body is preferably at least one water-supportable body selected from zeolites, molecular sieves, silica gel, and water-swelling gel-forming agents.

In the pressure-sensitive adhesive sheet fitted with die-adhering layer according to the invention, it is preferable that the pressure-sensitive adhesive layer has a pressure-sensitive adhesive force (peeling angle: 15°, drawing rate: 300 mm/min) at 23° C. of 1 N/10 mm width to 10 N/10 mm width when the laminated film is press-bonded (pressure: 1.47×10⁵ Pa, time: 1 minute) to a semiconductor wafer having a thickness of 0.6 mm by a heat lamination method at 40° C. in such a form that the die-adhering layer comes into contact with a surface of the semiconductor wafer and subsequently allowed to stand under an atmosphere of 23° C. for 30 minutes, and the pressure-sensitive adhesive layer has a pressure-sensitive adhesive force (peeling angle: 15°, drawing rate: 300 mm/min) at 23° C. of 5 N/10 mm width or less when the laminated film is press-bonded (pressure: 1.47×10⁵ Pa, time: 1 minute) to a semiconductor wafer having a thickness of 0.6 mm by a heat lamination method at 40° C. in such a form that the die-adhering layer comes into contact with a surface of the semiconductor wafer, subsequently allowed to stand under an atmosphere of 120° C. for 3 minutes, and thereafter allowed to stand under an atmosphere of 23° C. for 30 minutes.

The present invention also provides a process for producing a semiconductor device, in which a laminated film which includes a pressure-sensitive adhesive sheet including a pressure-sensitive adhesive layer, and a die-adhering layer laminated on the pressure-sensitive adhesive layer of the pressure-sensitive adhesive sheet is used, the process includes steps of:

attaching a semiconductor wafer to the die-adhering layer of the above-mentioned laminated film (laminated film including the water-supporting body-containing pressure-sensitive adhesive layer),

subjecting the semiconductor wafer having the laminated film attached thereto to a cut-processing treatment,

peeling semiconductor chips formed by the cut-processing treatment from the pressure-sensitive adhesive layer (water-supporting body-containing pressure-sensitive adhesive layer) together with the die-adhering layer, and

adhering the semiconductor chip fitted with the die-adhering layer to an adherend.

According to the laminated film of the invention, in a picking-up step in production steps of a semiconductor, a semiconductor chip fitted with a die-adhering layer can be can be peeled from a pressure-sensitive adhesive sheet with ease and with suppressing or preventing fouling of the die-adhering layer. Therefore, when the laminated film of the invention to be used in production steps of a semiconductor device is used, peeling can be easily achieved by heating with suppressing or preventing fouling of an adherend surface in the picking-up step at the production of the semiconductor, and a semiconductor chip fitted with a die-adhering layer where fouling of the die-adhering layer is suppressed or prevented can be effectively obtained. Accordingly, when the laminated film of the invention to be used in production steps of a semiconductor device is used, it becomes possible to produce a semiconductor device such as a semiconductor chip with an excellent productivity.

### BRIEF DESCRIPTION OF THE DRAWING

FIG. 1 is a cross-sectional schematic view showing one example of the laminated film of the invention.

### DESCRIPTION OF REFERENCE NUMERALS AND SIGNS

1 laminated film (pressure-sensitive adhesive sheet fitted with die-adhering layer)

2 pressure-sensitive adhesive sheet

2a base material

2b pressure-sensitive adhesive layer containing water-supporting body (water-supporting body-containing pressure-sensitive adhesive layer)

3 die-adhering layer

4 separator

### DETAILED DESCRIPTION OF THE INVENTION

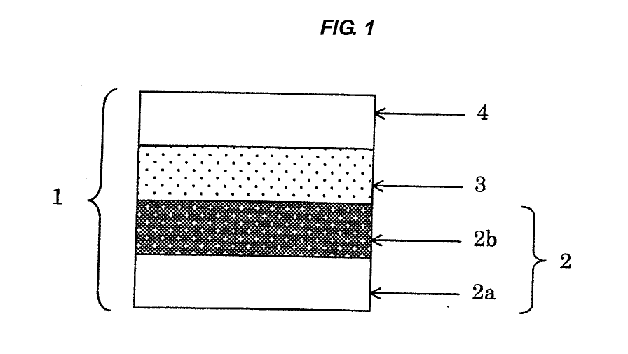

Embodiments of the present invention are described with reference to FIG. 1 but the invention is not limited to these examples. FIG. 1 is a cross-sectional schematic view showing one example of the laminated film of the invention. In FIG. 1, 1 is a laminated film (pressure-sensitive adhesive sheet fitted with die-adhering layer), 2 is a pressure-sensitive adhesive sheet, 2a is a base material, 2b is a pressure-sensitive adhesive layer containing a water-supporting body (water-supporting body-containing pressure-sensitive adhesive layer), 3 is a die-adhering layer, and 4 is a separator. However, parts that are unnecessary for the description are not given, and there are parts shown by magnifying, minifying, etc. in order to make the description easy.

The pressure-sensitive adhesive sheet 1 fitted with the die-adhering layer shown in FIG. 1 is constituted by the base material 2a, the water-supporting body-containing pressure-sensitive adhesive layer 2b formed on one surface of the base material 2a, the die-adhering layer 3 formed on the water-supporting body-containing pressure-sensitive adhesive layer 2b, and further the separator 4 formed on the die-adhering layer 3. In the pressure-sensitive adhesive sheet 1 fitted with the die-adhering layer, the pressure-sensitive adhesive sheet 2 is constituted by the base material 2a and the water-supporting body-containing pressure-sensitive adhesive layer 2b. In the pressure-sensitive adhesive sheet 1 fitted with the die-adhering layer of the invention, for the pressure-sensitive adhesive sheet 2, an intermediate layer such as a rubbery organic elastic layer can be arbitrarily provided between the base material 2a and the water-supporting body-containing pressure-sensitive adhesive layer 2b. Moreover, in the pressure-sensitive adhesive sheet fitted with the die-adhering layer of the invention, the pressure-sensitive adhesive sheet may have a constitution that the water-supporting body-containing pressure-sensitive adhesive layer is provided on one surface of the base material or may have a constitution that the water-supporting body-containing pressure-sensitive adhesive layer is provided on each surface of the base material. In this regard, in the pressure-sensitive adhesive sheet fitted with the die-adhering layer, in the case where the pressure-sensitive adhesive sheet has a constitution that the water-supporting body-containing pressure-sensitive adhesive layer is provided only one surface of the base material, the pressure-sensitive adhesive sheet may have a constitution that a pressure-sensitive adhesive layer containing no water-supporting body (water-supporting body-non-containing pressure-sensitive adhesive layer) is provided on the other surface of the base material.

### Base Material

The base material (supporting substrate) can be used as a supporting base material for the water-supporting body-containing pressure-sensitive adhesive layer and the like. As the base material, for example, suitable thin bodies, e.g., paper-based base materials such as paper; fiber-based base materials such as fabrics, non-woven fabrics, felts, and nets; metal-based base materials such as metal foils and metal plates; plastic base materials such as plastic films and sheets; rubber-based base materials such as rubber sheets; foamed bodies such as foamed sheets; and laminates thereof [particularly, laminates of plastic based materials with other base materials, laminates of plastic films (or sheets) each other, etc.] can be used. As the base material, one excellent in thermal resistance which does not melt at a heating treatment temperature of the water-supporting body-containing pressure-sensitive adhesive layer is preferred from the viewpoints of handling ability after heating and the like. In the invention, as the base material, plastic base materials such as plastic films and sheets can be suitably employed. Examples of raw materials for such plastic materials include olefinic resins such as polyethylene (PE), polypropylene (PP), and ethylene-propylene copolymers; copolymers using ethylene as a monomer component, such as ethylene-vinyl acetate copolymers (EVA), ionomer resins, ethylene-(meth)acrylic acid copolymers, and ethylene-(meth)acrylic acid ester (random, alternating) copolymers; polyesters such as polyethylene terephthalate (PET), polyethylene naphthalate (PEN), and polybutylene terephthalate (PBT); acrylic resins; polyvinyl chloride (PVC); polyurethanes; polycarbonates; polyphenylene sulfide (PPS); amide-based resins such as polyamides (Nylon) and whole aromatic polyamides (aramide); polyether ether ketones (PEEK); polyimides; polyetherimides; polyvinylidene chloride; ABS (acrylonitrile-butadiene-styrene copolymers); cellulose-based resins; silicone resins; and fluorinated resins. Moreover, as the material of the base material, a polymer such as a cross-linked body of each of the above resins can also be used. These raw materials may be used solely or two or more kinds thereof can be used in combination.

In the case where a plastic base material is used as the base material, deformation properties such as an elongation percent may be controlled by a stretching treatment or the like.

The surface of the base material may be subjected to a commonly used surface treatment, e.g., an oxidation treatment by a chemical or physical method, such as a chromate treatment, ozone exposure, flame exposure, exposure to high-voltage electric shock, or an ionizing radiation treatment, or may be subjected to a coating treatment with a coating agent such as an anchor coating agent, a primer, or an adhesive in order to enhance the close adhesion to the water-supporting body-containing pressure-sensitive adhesive layer, the holding properties, and the like. Since the pressure of the water vapor is imparted not only to the die-adhering layer side of the water-supporting body-containing pressure-sensitive adhesive layer but also to the base material side at the time when the pressure-sensitive adhesive sheet is peeled from the die-adhering layer through vaporization of the water contained in the water-supporting body in the water-supporting body-containing pressure-sensitive adhesive layer by heating, it is preferable to perform the above-described surface treatment or coating treatment particularly on the surface of the base material at the water-supporting body-containing pressure-sensitive adhesive layer side. Both of the surface treatment and the coating treatment may be applied. Examples of the anchor coating agent include organic titanate-based, polyethyleneimine-based, polybutadiene-based, isocyanate-based, and polyester-based anchor coating agents. Moreover, examples of the adhesive include polyester-based, polyurethane-based, and polyester-based adhesives. As the adhesive, polyurethane-based adhesives can be suitably used.

In this regard, in the case where the pressure-sensitive adhesive sheet fitted with the die-adhering layer has a constitution that it is wound in a roll form without protecting the die-adhering layer with a separator, for imparting peeling ability against the die-adhering layer surface to the rear surface of the base material, for example, a coating treatment with a releasant (releasing agent) such as a silicone-based resin or a fluorine-based resin may be applied.

Incidentally, the base material may contain various additives (coloring agents, fillers, plasticizers, antiaging agents, antioxidants, surfactants, flame retardants, etc.) within the range where the advantages and the like of the invention are not impaired.

The thickness of the base material is not particularly restricted and can be appropriately selected depending on strength, flexibility, intended purpose of use, and the like. For example, the thickness is generally 1,000 μm or less (e.g., 1 μm to 1,000 μm), preferably 1 μm to 500 μm, further preferably 3 μm to 300 μm, and particularly about 5 μm to 250 μm but is not limited thereto. In this regard, the base material may have any form of a single layer form and a laminated form.

### Water-Supporting Body-Containing Pressure-Sensitive Adhesive Layer

The water-supporting body-containing pressure-sensitive adhesive layer is a pressure-sensitive adhesive layer containing a water-supporting body. It is sufficient that the water-supporting body is contained in the pressure-sensitive adhesive layer and its form when contained therein is not particularly limited but a dispersed form is preferable. The form (structure) that the water-supporting body is dispersed in the pressure-sensitive adhesive layer means a form (structure) that the water-supporting body is dispersed in a base polymer and, more specifically, means a form (structure) that domains composed of the water-supporting body are dispersed (lie scattered) in a matrix composed of the base polymer. In the pressure-sensitive adhesive sheet fitted with the die-adhering layer according to the invention, since the pressure-sensitive adhesive composition constituting the water-supporting body-containing pressure-sensitive adhesive layer to be in contact with the die-adhering layer has such form and composition, when the pressure-sensitive adhesive sheet fitted with the die-adhering layer is heated after a semiconductor wafer or the like is attached on the pressure-sensitive adhesive sheet fitted with the die-adhering layer and an anticipated role such as temporary fixing is finished, the water contained in the water-supporting body in the water-supporting body-containing pressure-sensitive adhesive layer spouts as a water vapor from the surface of the water-supporting body-containing pressure-sensitive adhesive layer and presses the contact surface of the die-adhering layer on the water-supporting body-containing pressure-sensitive adhesive layer, so that the die-adhering layer can be easily peeled from the water-supporting body-containing pressure-sensitive adhesive layer of the pressure-sensitive adhesive sheet.

The content of the water-supporting body in the pressure-sensitive adhesive composition constituting the water-supporting body-containing pressure-sensitive adhesive layer can be appropriately selected in the range where the adhesiveness and easy peeling ability of the pressure-sensitive adhesive sheet are not impaired. For example, the content is in the range of 3% by weight to 50% by weight, preferably 5% by weight to 30% by weight, further preferably 10% by weight to 20% by weight based on the whole amount of the pressure-sensitive adhesive composition (solid matter excluding the water-supporting body). When the content of the water-supporting body is less than 3% by weight based on the whole amount of the pressure-sensitive adhesive composition, there is a case where the peeling of the pressure-sensitive adhesive sheet becomes difficult. On the other hand, when the content of the water-supporting body is more than 50% by weight based on the whole amount of the pressure-sensitive adhesive composition, there is a concern that smooth peeling of the pressure-sensitive adhesive sheet is impaired through a decrease in adhesive force of the pressure-sensitive adhesive sheet or a decrease in dispersing property of the water-supporting body.

Moreover, in the water-supporting body-containing pressure-sensitive adhesive layer, it is important that the gel fraction (insoluble fraction) is 90% by weight or more. The gel fraction of the water-supporting body-containing pressure-sensitive adhesive layer is preferably 92% by weight or more, further preferably 96% by weight or more. When the gel fraction of the water-supporting body-containing pressure-sensitive adhesive layer is 90% by weight or more, the water-supporting body-containing pressure-sensitive adhesive layer can be easily peeled from the die-adhering layer in the pressure-sensitive adhesive sheet and hence it is possible to exhibit a good picking-up property. Moreover, at the time when the water-supporting body-containing pressure-sensitive adhesive layer is peeled from the die-adhering layer, the fouling of the die-adhering layer due to a remaining of the pressure-sensitive adhesive composition on the die-adhering layer though cohesive failure of the water-supporting body-containing pressure-sensitive adhesive layer can be effectively suppressed or prevented.

In the invention, the gel fraction of the water-supporting body-containing pressure-sensitive adhesive layer can be measured by the following measurement method.

### <Gel Fraction Measurement Method>

About 0.1 g of a sample is sampled from the water-supporting body-containing pressure-sensitive adhesive layer (not subjected to heat treatment) and precisely weighed (Weight of Sample) and, after the sample is wrapped in a mesh-type sheet, is immersed in about 50 mL of toluene at room temperature for 1 week. Thereafter, a solvent-insoluble matter (content in the mesh-type sheet) is taken out of the toluene and dried at 130° C. for about 2 hours, a solvent-insoluble matter after drying is weighed (Weight after Immersion and Drying), and then the gel fraction (% by weight) is calculated according to the following equation (a).

Gel Fraction (% by weight)=[(Weight after Immersion and Drying)/(Weight of Sample)]×100 (a)

Incidentally, the gel fraction of the water-supporting body-containing pressure-sensitive adhesive layer can be controlled by adjusting the composition of the base polymer of the pressure-sensitive adhesive for forming the water-supporting body-containing pressure-sensitive adhesive layer, the kind and content of the crosslinking agent to be added to the pressure-sensitive adhesive, the kind and content of the water-supporting body, and the like.

### (Water-Supporting Body)

The water-supporting body is one wherein water is supported or held on a support through adsorption, capture, or the like. The adsorption of water on the support is physical adsorption, adsorption by electrostatic attraction, chemical adsorption, or the like. It is important that such a water-supporting body is one capable of desorption (elimination), release, or the like of the water supported on the support by a heat treatment or the like. The water-supporting body can be used solely or two or more kinds thereof can be used in combination.

It is important that the support is one having an ability to be dispersed in pressure-sensitive adhesive components (such as the base polymer) constituting the pressure-sensitive adhesive composition or precursors thereof (such as a prepolymer) without dissolution and to absorb and to hold water and also having characteristics of desorbing water by heating or the like. The support can be appropriately selected from among various water-supportable bodies such as water-adsorbing/capturing agents, water swelling clay minerals, and water-swelling gel-forming agents and used. The support is suitably one having a form of a powder granule or a powder (a water-supportable powder granule). The support may be either synthetic one or natural one. The support can be used solely or two or more kinds thereof can be used in combination.

Specifically, as the support, there can be, for example, used water-supportable bodies, e.g., water-adsorbing/capturing agents such as zeolite, Molecular Sieves (product name), silica gel, magnesium silicate, zirconia, alumina, bauxite, magnesium oxide, titanium oxide, sepiolite, activated clay, active carbon, charcoal, and bone charcoal; water swelling clay minerals such as smectite clay minerals; and water-swelling gel-forming agents. In the water-adsorbing/capturing agents, Molecular Sieves (product name; manufactured and commercialized by Union Showa K.K.; synthetic zeolite; metal salts of synthetic crystalline aluminosilicate) may be any of A type, X type, Y type, and the like and, for example, Molecular Sieve 3A, Molecular Sieve 4A, Molecular Sieve 13X, and the like may be exemplified.

As the smectite clay minerals in the water-swelling clay minerals, there may be mentioned phyllosilicate minerals having a layered structure, which are montmorillonite minerals. More specifically, as the smectite clay minerals, there may be, for example, montmorillonite, beidellite, nontronite, saponite, hectorite, sauconite, and stevensite.

The water-swelling gel-forming agent is not particularly restricted so long as it can form gel through swelling with water. Examples of representative water-swelling gel-forming agents include carboxyvinyl polymers such as poly(meth)acrylic acid and sodium poly(meth)acrylate (the carboxyl group may form a salt), styrene-maleic anhydride copolymers, polyacrylamide, starch and derivatives thereof, polyalkylene oxide-based water-absorbable resins, agar, arginine, arabinogalactan, galactomannan, cellulose and derivatives thereof (carboxymethyl cellulose, etc.), dextran, gelatin, pectin, hyaluronic acid, gellan gum, collagen, casein, and xanthan gum. The water-swelling gel-forming agent may be crosslinked with a crosslinking agent. As the corsslinking agent, for example, in the case of a carboxyvinyl polymer, polyvalent metal compounds such as calcium chloride, magnesium chloride, aluminum chloride, aluminum sulfate, potash alum, ferric sulfate, aluminum hydroxide, aluminum silicate, aluminum phosphate, iron citrate, magnesium oxide, calcium oxide, and zinc oxide are used. Among the above-described water-swelling gel-forming agents, crosslinked carboxyvinyl polymers such as crosslinked polyacrylic acid are preferable.

As the support, powder granular one (powder one) is preferable. The average particle diameter of the powder granular support is not particularly limited, but is preferably 0.1 μm to 20 μm, more preferably 1 μm to 20 μm from the viewpoints of dispersing property and the like.

The water-supporting body can be prepared by incorporating or supporting water (incorporating or supporting water through adsorption, capture, or the like) onto the support. For example, the water-supporting body can be prepared by immersing the support in water or spraying water or water vapor onto the support. The water content in the water-supporting body varies depending on water-absorbing capacity or water-adsorbing capacity of the support but generally about 30% by weight or more and less than 100% by weight, preferably about 40% by weight to 90% by weight, further preferably about 50% by weight to 80% by weight, based on the total weight of the water-supporting body.

### (Pressure-Sensitive Adhesive)

As the pressure-sensitive adhesive for forming the water-supporting body-containing pressure-sensitive adhesive layer, it is important to use a pressure-sensitive adhesive whose gel fraction becomes a prescribed value at the time when the water-supporting body-containing pressure-sensitive adhesive layer is formed and there can be suitably used one which does not inhibit the diffusion of the water in the water-supporting body as water vapor during heating to the interface with the die-adhering layer. Specifically, as the pressure-sensitive adhesive, for example, a pressure-sensitive adhesive agent having the above-described characteristics can be suitably selected from known pressure-sensitive adhesives such as acrylic pressure-sensitive adhesives, rubber-based pressure-sensitive adhesives, vinyl alkyl ether-based pressure-sensitive adhesives, silicone-based pressure-sensitive adhesives, polyester-based pressure-sensitive adhesives, polyamide-based pressure-sensitive adhesives, urethane-based pressure-sensitive adhesives, fluorine-based pressure-sensitive adhesives, styrene-diene block copolymer-based pressure-sensitive adhesives, and creeping property-improvable pressure-sensitive adhesives where a heat-meltable resin having a melting point of about 200° C. or lower is blended in these pressure-sensitive adhesives (see, e.g., JP-A-56-61468, JP-A-61-174857, JP-A-63-17981, JP-A-56-13040, and the like, which are herein incorporated by reference). Moreover, as the pressure-sensitive adhesive, a radiation ray-curable pressure-sensitive adhesive (or an energy ray curable pressure-sensitive adhesive) can be also used. The pressure-sensitive adhesives can be used solely or two or more kinds thereof can be used in combination. Incidentally, in the case where the pressure-sensitive adhesive is constituted by two or more kinds of pressure-sensitive adhesives, it is important that the pressure-sensitive adhesive constituted by two or more kinds of pressure-sensitive adhesives has the above-described characteristics.

In the invention, as the pressure-sensitive adhesive, rubber-based pressure-sensitive adhesives using natural rubber or any of various synthetic rubbers (such as polyisoprene rubber, styrene-butadiene rubber, styrene-isoprene-styrene block copolymeric rubber, styrene-butadiene-styrene block copolymeric rubber, reclaimed rubber, butyl rubber and isobutylene) as a base polymer or acrylic pressure-sensitive adhesives using an acrylic polymer as a base polymer can be suitably used. Of these, acrylic pressure-sensitive adhesives are particularly preferred.

As the acrylic pressure-sensitive adhesive, those containing an acrylic polymer using one or more kinds of (meth)acrylic acid alkyl esters as monomer component(s) can be suitably used. Examples of the (meth)acrylic acid alkyl esters include (meth)acrylic acid alkyl esters having an alkyl group having 1 to 20 carbon atoms, such as methyl(meth)acrylate, ethyl(meth)acrylate, propyl(meth)acrylate, isopropyl(meth)acrylate, butyl(meth)acrylate, isobutyl(meth)acrylate, s-butyl(meth)acrylate, t-butyl(meth)acrylate, pentyl(meth)acrylate, hexyl(meth)acrylate, heptyl(meth)acrylate, octyl(meth)acrylate, 2-ethylhexyl(meth)acrylate, isooctyl(meth)acrylate, nonyl(meth)acrylate, isononyl(meth)acrylate, decyl(meth)acrylate, isodecyl(meth)acrylate, undecyl(meth)acrylate, dodecyl(meth)acrylate, tridecyl(meth)acrylate, tetradecyl(meth)acrylate, pentadecyl(meth)acrylate, hexadecyl(meth)acrylate, heptadecyl(meth)acrylate, octadecyl(meth)acrylate, nonadecyl(meth)acrylate, and eicosyl(meth)acrylate, and the like. As the (meth)acrylic acid alkyl esters, (meth)acrylic acid alkyl esters having an alkyl group having 2 to 14 carbon atoms are suitable and further preferred are (meth)acrylic acid alkyl esters having an alkyl group having 2 to 10 carbon atoms. Incidentally, the alkyl group of the (meth)acrylic acid alkyl ester may be any of linear chain and branched chain ones.

Among such (meth)acrylic acid alkyl esters, an acrylic acid alkyl ester having an alkyl group having 6 to 10 carbon atoms [CH₂═CHCOOR (R is an alkyl group having 6 to 10 carbon atoms)] is preferred and among them, an acrylic acid alkyl ester having an alkyl group having 8 or 9 carbon atoms is suitable. When the acrylic acid alkyl ester having an alkyl group having 6 to 10 carbon atoms is used as the (meth)acrylic acid alkyl ester, the peeling force of the water-supporting body-containing pressure-sensitive adhesive layer against the die-adhering layer can be controlled to an appropriate degree and a good picking-up property can be exhibited. Moreover, the water-supporting body-containing pressure-sensitive adhesive layer can exhibits an appropriate close adhesion with the die-adhering layer and thus chip fly at the dicing can be effectively suppressed or prevented. In the invention, as the acrylic acid alkyl ester having an alkyl group having 6 to 10 carbon atoms, 2-ethylhexyl acrylate and isooctyl acrylate are particularly preferred.

In the case where the acrylic acid alkyl ester having an alkyl group having 6 to 10 carbon atoms is used as the (meth)acrylic acid alkyl ester, it is suitable that the content of the acrylic acid alkyl ester having an alkyl group having 6 to 10 carbon atoms is preferably 50 to 99% by mol, more preferably 80 to 99% by mol, particularly 90 to 99% by mol, based on the whole monomer components. When the content of the acrylic acid alkyl ester having an alkyl group having 6 to 10 carbon atoms is less than 50% by mol based on the whole monomer components, the peeling force of the water-supporting body-containing pressure-sensitive adhesive layer against the die-adhering layer becomes too large, so that there is a case where the pick-up property decreases. On the other hand, when the content exceeds 99% by mol, the pressure-sensitive adhesiveness decreases and there is a case that chip fly is generated at the dicing.

Moreover, according to the invention, in the acrylic polymer as a base polymer of the acrylic pressure-sensitive adhesive, (meth)acrylic acid esters having an alicyclic hydrocarbon group such as cyclopentyl(meth)acrylate, cyclohexyl(meth)acrylate, and isobornyl(meth)acrylate and (meth)acrylic acid esters having an aromatic hydrocarbon group can be also used as a monomer component.

Incidentally, for the purpose of modification of the cohesive force, the adhesive force to the die-adhering layer, the thermal resistance, the crosslinking ability, and the like, the above-described acrylic polymer may contain a unit corresponding to another monomer component copolymerizable with the above-described (meth)acrylic acid alkyl esters (a copolymerizable monomer component) according to needs. One or more kinds of the copolymerizable monomer components can be used. As the copolymerizable monomer components, polar group-containing monomers, polyfunctional monomers or oligomers, and the like may be mentioned. In this regard, in the invention, “polyfunctional oligomers” are also included in the category of the monomers for the sake of convenience.

Examples of the polar group-containing monomers include carboxyl group-containing monomers such as (meth)acrylic acid (acrylic acid, methacrylic acid), carboxyethyl acrylate, carboxypentyl acrylate, itaconic acid, maleic acid, fumaric acid, crotonic acid, and isocrotonic acid; acid anhydride group-containing monomers such as maleic anhydride and itaconic anhydride; hydroxyl group-containing monomers such as hydroxyethyl(meth)acrylate, hydroxypropyl(meth)acrylate, hydroxybutyl(meth)acrylate, hydroxyhexyl(meth)acrylate, hydroxyoctyl(meth)acrylate, hydroxydecyl(meth)acrylate, hydroxylauryl(meth)acrylate, and (4-hydroxymethylcyclohexyl)methyl methacrylate; glycol-based acrylic ester monomers such as polyethylene glycol(meth)acrylate, polypropylene glycol(meth)acrylate, methoxyethylene glycol(meth)acrylate, and methoxypolypropylene glycol(meth)acrylate; sulfonic acid group-containing monomers such as styrenesulfonic acid, sodium vinylsulfonate, allylsulfonic acid, 2-(meth)acrylamido-2-methylpropanesulfonic acid, (meth)acrylamidopropanesulfonic acid, sulfopropyl(meth)acrylate, and (meth)acryloyloxynaphthalenesulfonic acid; phosphoric acid group-containing monomers such as 2-hydroxyethylacryloyl phosphate; (N-substituted)amide-based monomers such as (meth)acrylamide, N,N-dimethyl(meth)acrylamide, N-butyl(meth)acrylamide, N-methylol(meth)acrylamide, N-methylolpropane(meth)acrylamide, N-methoxymethyl(meth)acrylamide, and N-butoxymethyl(meth)acrylamide; aminoalkyl(meth)acrylate-based monomers such as aminoethyl(meth)acrylate, N,N-dimethylaminoethyl(meth)acrylate, and t-butylaminoethyl(meth)acrylate; alkoxyalkyl(meth)acrylate-based monomers such as methoxyethyl(meth)acrylate and ethoxyethyl(meth)acrylate; maleimide-based monomers such as N-cyclohexylmaleimide, N-isopropylmaleimide, N-laurylmaleimide, and N-phenylmaleimide; itaconimide-based monomers such as N-methylitaconimide, N-ethylitaconimide, N-butylitaconimide, N-octylitaconimide, N-2-ethylhexylitaconimide, N-laurylitaconimide, and N-cyclohexylitaconimide; succinimide-based monomers such as N-(meth)acryloyloxymethylenesuccinimide, N-(meth)acryloyl-6-oxyhexamethylenesuccinimide, and N-(meth)acryloyl-8-oxyoctamethylenesuccinimide; vinyl ester-based monomers such as vinyl acetate and vinyl propionate; heterocycle-containing monomers such as N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, and N-vinylcaprolactam; N-vinylcarboxylic acid amides; vinyl alkyl ether-based monomers such as vinyl methyl ether and vinyl ethyl ether; cyanoacrylate monomers such as acrylonitrile and methacrylonitrile; epoxy group-containing monomers such as glycidyl(meth)acrylate and methylglycidyl(meth)acrylate; heterocycle-containing (meth)acrylic acid esters such as tetrahydrofurfuryl (meth)acrylate; and silicon atom-containing monomers such as silicone (meth)acrylate. Among these polar group-containing monomers, carboxyl group-containing monomers such as acrylic acid and acid anhydride group-containing monomers are particularly preferred.

The content of the polar group-containing monomer is in the range of preferably 1% by mol to 10% by mol, further preferably 5% by mol to 10% by mol based on the whole amount of the monomer components. When the content of the polar group-containing monomer component is less than 1% by mol based on the whole amount of the monomer components, there is a case where crosslinking is insufficient and the picking-up property decreases. On the other hand, when the content exceeds 10% by mol, the polarity of the pressure-sensitive adhesive increases and there is a case where peeling becomes difficult through an increase in interaction with the die-adhering layer.

Examples of the polyfunctional monomer include hexanediol di(meth)acrylate, (poly)ethylene glycol di(meth)acrylate, (poly)propylene glycol di(meth)acrylate, neopentyl glycol di(meth)acrylate, pentaerythritol tri(meth)acrylate, pentaerythritol di(meth)acrylate, pentaerythritol(meth)acrylate, dipentaerythritol hexa(meth)acrylate, trimethylolpropane tri(meth)acrylate, tetramethylolmethane tri(meth)acrylate, allyl(meth)acrylate, vinyl(meth)acrylate, divinylbenzene, butyl di(meth)acrylate, and hexyl di(meth)acrylate. Examples of the polyfunctional oligomer include oligomers having a (meth)acryloyl group at the molecular end, such as polyfunctional urethane(meth)acrylate-based oligomers, polyfunctional ester(meth)acrylate-based oligomers, polyfunctional epoxy(meth)acrylate-based oligomers, and polyfunctional melamine(meth)acrylate-based oligomers.

It is desirable that the amount of the polyfunctional monomer or oligomer to be used is 7% by weight or less (e.g., 0.01% by weight to 7% by weight, preferably 0.5% by weight to 5% by weight, further preferably 0.6% by weight to 3% by weight) based on the whole amount of the monomer components. When the amount of the polyfunctional monomer or oligomer to be used exceeds 7% by weight based on the whole amount of the monomer components, there is a concern that the dispersing property of water-supporting body decreases or the pressure-sensitive adhesive force decreases due to excessively high cohesive force of the acrylic pressure-sensitive adhesive. In this regard, when the amount of the polyfunctional monomer or oligomer to be used is less than 0.01% by weight based on the whole amount of the monomer components, for example, the cohesive force of the acrylic pressure-sensitive adhesive is apt to decrease.

With regard to the copolymerizable monomer component(s), examples of the monomer components other than the above-mentioned ones include styrene-based monomers such as styrene, vinyltoluene, and α-methylstyrene; olefins or diener such as ethylene, butadiene, isoprene, and isobutylene; halogen atom-containing monomers such as vinyl chloride and vinylidene chloride; and fluorine atom-containing monomers such as fluorinated (meth)acrylates.

Incidentally, the acrylic pressure-sensitive adhesive can be prepared using the above-mentioned monomer component(s) and utilizing any of known polymerization techniques such as solution polymerization (e.g., radical polymerization, anion polymerization, cation polymerization, etc.), emulsion polymerization, and photopolymerization (e.g., ultraviolet ray (UV) polymerization, etc.).

### (Crosslinking Agent)

In the invention, in order to control the gel fraction of the water-supporting body-containing pressure-sensitive adhesive layer to 90% by weight or more, it is preferable that the water-supporting body-containing pressure-sensitive adhesive layer has a structure crosslinked with a crosslinking agent. By using the crosslinking agent, the gel fraction of the water-supporting body-containing pressure-sensitive adhesive layer can be easily controlled to 90% by weight or more. As such a crosslinking agent, there can be suitably used one capable of causing a crosslinking reaction by heat.

In this regard, the crosslinking agent may be one which constructs a crosslinked structure through the reaction with a functional group such as a hydroxyl group, a carboxyl group, an amino group, or an amide group which has been introduced as a crosslinking base point into the base polymer structure in the pressure-sensitive adhesive composition, may be one which constructs a crosslinked structure through the reaction with a crosslinking agent-reactive component (e.g., a polyol compound, a polycarboxylic acid compound, a polyamine compound, etc.) which has been added into the pressure-sensitive adhesive composition, or may be one which constructs a crosslinked structure between crosslinking agents. The crosslinking agents can be used solely or two or more kinds thereof can be used in combination. A temperature at which the crosslinking reaction proceeds is preferably a temperature similar to or higher than the temperature at which water in the water-supporting body in the pressure-sensitive adhesive composition boils (e.g., in the range of 80° C. to 180° C.), particularly suitably in the range of 90° C. to 150° C.

Examples of representative crosslinking agents include isocyanate-based crosslinking agents, epoxy-based crosslinking agents, melamine-based crosslinking agents, amine-based crosslinking agents, aziridine-based crosslinking agents, metal chelate compounds, peroxide-based crosslinking agents, urea-based crosslinking agents, metal alkoxide-based crosslinking agents, metal salt-based crosslinking agents, carbodiimide-based crosslinking agents, and oxazoline-based crosslinking agents as well as blocked crosslinking agents obtained by blocking the crosslinkable group of each of these crosslinking agents with a blocking agent. As the crosslinking agent, a blocked crosslinking agent which does not induce a crosslinking reaction until the time when peeling is performed under heating can be suitably used. Incidentally, the blocked crosslinking agent can be used solely or two or more kinds thereof can be used in combination. Moreover, as the crosslinking agent, a blocked crosslinking agent and an unblocked crosslinking agent may be used in combination.

More specifically, the above-described blocked crosslinking agent is such a crosslinking agent that the crosslinking-reactive functional groups in the crosslinking agent are inactivated with the blocking agent before heating and at least two or more functional groups in one molecule are activated through the dissociation of the blocking agent from the functional group by heating. In the invention, water vapor spouts from the water-supporting body in the water-supporting body-containing pressure-sensitive adhesive layer by heating to press the die-adhering layer, thereby easy peeling between the die-adhering layer and the water-supporting body-containing pressure-sensitive adhesive layer being realized. However, after the water vapor has completely spouted out, there is a concern that the die-adhering layer and the water-supporting body-containing pressure-sensitive adhesive layer are re-adhered. Therefore, by inducing a crosslinking reaction in the water-supporting body-containing pressure-sensitive adhesive layer through activation of the blocked corsslinking agent by heating at the time when water vapor is generated, the re-adhesion of the die-adhering layer and the water-supporting body-containing pressure-sensitive adhesive layer can be effectively suppressed or prevented. In order to use the crosslinking agent for the aforementioned purpose, it is desirable that the dissociation temperature of the blocking agent from the crosslinking reaction-reactive functional group is a temperature similar to or higher than the temperature at which the water in the water-supporting body in the water-supporting body-containing pressure-sensitive adhesive layer boils (e.g., 80 to 180° C., preferably 90 to 150° C.).

As the blocked crosslinking agent, a commercially available product can be used and also the blocked crosslinking agent may be a blocked crosslinking agent obtainable by inactivating any of various crosslinking agents with a blocking agent by a conventionally known method. As the blocked crosslinking agent, particularly, a blocked isocyanate (isocyanate-based blocked crosslinking agent) obtainable by blocking an isocyanate compound with a blocking agent can be suitably used.

As the isocyanate compound for use in the blocked isocyanate, a compound having two or more isocyanate groups in one molecule is preferable. Examples thereof include aliphatic polyisocyanates such as ethylene diisocyanate, tetramethylene diisocyanate, hexamethylene diisocyanate (HDI), and dodecamethylene diisocyanate;

alicyclic polyisocyanates such as cyclopentylene diisocyanate, cyclohexylene diisocyanate, isophorone diisocyanate (IPDI), dicyclohexylmethane-4,4′-diisocyanate (hydrogenated MDI), and methylcyclohexylene diisocyanate (hydrogenated TDI); aromatic polyisocyanates such as 1,3-phenylene diisocyanate, 1,4-phenylene diisocyanate, 2,4-tolylene diisocyanate (TDI), 2,6-tolylene diisocyanate (TDI), 2,2′-diphenylmethane diisocyanate (MDI), 2,4′-diphenylmethane diisocyanate (MDI), 4,4′-diphenylmethane diisocyanate (MDI), 3-chloro-4-methylphenyl diisocyanate, and 4-chlorophenyl diisocyanate; aromatic-aliphatic diisocyanates such as m-xylylene diisocyanate (XDI), p-xylylene diisocyanate (XDI), and α,α,α′,α′-tetramethylxylylene diisocyanate (TMXDI); polymethylene polyphenyl polyisocyanate; isocyanate adducts such as a trimethylolpropane/tolylene diisocyanate trimer adduct (manufactured by Nippon Polyurethane Industry Co., Ltd., product name “COLONATE L”), a trimethylolpropane/hexamethylene diisocyanate trimer adduct (manufactured by Nippon Polyurethane Industry Co., Ltd., product name “COLONATE HL”), and an isocyanurate compound of hexamethylene diisocyanate (manufactured by Nippon Polyurethane Industry Co., Ltd., product name “COLONATE HX”); and modified products of the above-described individual polyisocyanates.

Moreover, examples of the blocking agents for the isocyanate compounds include lactams such as ε-caprolactam, δ-valerolactam, and γ-butyrolactam; oximes such as methyl ethyl ketoxime, methyl isobutyl ketoxime, methyl isoamyl ketoxime, acetophenone oxime, benzophenone oxime, and cyclohexanone oxime; phenols such as phenol, cresol, ethylphenol, butylphenol, nonylphenol, catechol, and nitrophenol; alcohols such as methanol, ethanol, isopropyl alcohol, butanol, cyclohexanol, and trimethylolpropane; mercaptans such as butylmercaptan and dodecylmercaptan; active methylene compounds such as dimethyl malonate, diethyl malonate, methyl acetoacetate, ethyl acetoacetate, and acetylacetone; amides such as acetanilide and acetamide; imides such as succinic acid imide and maleic acid imide; pyrazoles such as 3,5-dimethylpyrazole; triazoles such as 1,2,4-triazole; sulfites such as sodium hydrogen sulfite; and N,N′-diarylformamidines such as N,N′-diphenylformamidine, N,N′-bis(2-methylphenyl)formamidine, N,N′-bis(3-methylphenyl)formamidine, N,N′-bis(4-methylphenyl)formamidine, and N,N′-bis(3,5-dimethylphenyl)formamidine. These blocking agents can be used solely or two or more kinds thereof can be used in combination. Among the above-described blocking agents, N,N′-diarylformamidines are preferable in view of a long pot life of the pressure-sensitive adhesive composition and proceeding of the crosslinking reaction at relatively low temperature (e.g., 80 to 120° C.).

As the blocked isocyanate, a commercially available product can be used and also the blocked isocyanate can be prepared by a known method and used. The blocked isocyanate can be obtained by stirring an isocyanate compound and a blocking agent at a temperature of about 0 to 200° C. in a solvent and separating a product thereof using a known separation and purification method such as concentration, filtration, extraction, crystallization, and/or distillation.

The content of the crosslinking agent in the pressure-sensitive composition constituting the water-supporting body-containing pressure-sensitive adhesive layer can be suitably selected in the range where the adhesiveness and easy peeling ability of the pressure-sensitive adhesive sheet are not impaired but is, for example, in the range of 0.1% by weight to 20% by weight, preferably 3% by weight to 18% by weight, further preferably 7% by weight to 15% by weight.

In addition to the base polymer as a main body of the pressure-sensitive adhesive, the water-supporting body-containing pressure-sensitive adhesive layer or the pressure-sensitive adhesive composition constituting the water-supporting body-containing pressure-sensitive adhesive layer may contain, for example, appropriate additives such as photopolymerization initiators, thermal polymerization initiators, tackifiers (e.g., those composed of rosin derivative resins, polyterpene resins, petroleum resins, oil-soluble phenol resins, or the like, which are solid, semi-solid, or liquid at ordinary temperature), plasticizers, antiaging agents, antioxidants, thickening agents (viscosity regulators), surfactants, and coloring agents. Moreover, the water-supporting body-containing pressure-sensitive adhesive layer or the pressure-sensitive adhesive composition may contain catalysts for promoting the dissociation of the blocked crosslinking agent and crosslinking agent-reactive components (e.g., polyol compounds, polycarboxylic acid compounds, polyamine compounds, etc.) for the purpose of enhancing cohesive force of the pressure-sensitive adhesive layer or enhancing the peeling ability at heating.

Incidentally, in the invention, it is also possible to perform the crosslinking treatment by irradiation with an electron beam or ultraviolet ray in place of the use of crosslinking agent or with the use of the crosslinking agent.

### (Manufacturing Method of Water-Supporting Body-Containing Pressure-Sensitive Adhesive Layer)

The water-supporting body-containing pressure-sensitive adhesive layer can be produced via a step of forming a water-supporting body-containing pressure-sensitive adhesive layer constituted by a pressure-sensitive adhesive composition containing a water-supporting body (a water-supporting body-containing pressure-sensitive adhesive composition) on a separator (release liner) or a base material. In the case where the water-supporting body-containing pressure-sensitive adhesive layer is formed on the separator, a pressure-sensitive adhesive sheet having the water-supporting body-containing pressure-sensitive adhesive layer laminated on a base material can be manufactured by transcribing (transferring) the water-supporting body-containing pressure-sensitive adhesive layer on the separator to the base material.

The forming method of the water-supporting body-containing pressure-sensitive adhesive layer is not particularly limited so long as it is a method capable of manufacturing a form (structure) that the water-supporting body is dispersed in a matrix composed of the base polymer (e.g., a form or structure dispersed as domains). In this regard, as the water-supporting body-containing pressure-sensitive adhesive composition, there can be suitably used a pressure-sensitive adhesive composition where the water-supporting body is dispersed in the base polymer or a raw material thereof.

For example, in the case where the water-supporting body-containing pressure-sensitive adhesive layer is formed of a pressure-sensitive adhesive using as the base polymer a polymer prepared by solution polymerization, the water-supporting body-containing pressure-sensitive adhesive layer can be manufactured by dispersing a water-supporting body into a solution containing the base polymer to prepare a water-supporting body-containing pressure-sensitive adhesive solution, applying the water-supporting body-containing pressure-sensitive adhesive solution on the separator or the base material utilizing a known application technique to form a coated film, and subsequently subjecting it to a drying step. However, depending on the drying temperature at the drying step, it is foreseen that water has been vaporized from the water-supporting body. In the case where water is thus reduced or lost from the water-supporting body in the water-supporting body-containing pressure-sensitive adhesive layer by vaporization or the like after the drying step of the coated film, it is possible to supply water again to the support for letting the support support water by a method of spraying water and/or water vapor on the surface of the coated film or a method of letting the dried coated film pass through a water vessel together with the release liner or base material on which the dried coated film is formed, whereby it is possible to obtain the water-supporting body-containing pressure-sensitive adhesive layer.

Moreover, in the case where the water-supporting body-containing pressure-sensitive adhesive layer is formed of a pressure-sensitive adhesive using as the base polymer a polymer prepared by solution polymerization, it is foreseen that the number of steps after drying of the coated film may increase in the production process of the pressure-sensitive adhesive sheet. Therefore, in view of reduction of the number of steps in the production process of the pressure-sensitive adhesive sheet and improvement of production efficiency, as the production method of the pressure-sensitive adhesive (particularly, an acrylic pressure-sensitive adhesive), it is desirable to use a method utilizing photopolymerization (particularly, UV polymerization). The following will describe the details of the process for producing the pressure-sensitive adhesive sheet using the UV polymerization.

For example, the water-supporting body-containing pressure-sensitive adhesive layer can be formed by applying a photopolymerizable composition containing a photopolymerizable prepolymer and a water-supporting body on a separator or a base material and subsequently curing the prepolymer by light irradiation. In order to attain a form (structure) that the water-supporting body is dispersed in a matrix composed of the base polymer after curing, the photopolymerizable composition preferably has a state (or a form) that the water-supporting body is homogeneously (or almost homogeneously) dispersed in the photopolymerizable prepolymer.

The photopolymerizable prepolymer can be produced by adding a photopolymerization initiator to a photopolymerizable monomer and irradiating it with light to achieve partial polymerization (prepolymerization). As the photopolymerizable monomer, usually, there is used a constitutional monomer for the base polymer (e.g., an acrylic polymer) of the pressure-sensitive adhesive composition constituting the water-supporting body-containing pressure-sensitive adhesive layer. For example, in the case where the base polymer is the acrylic polymer, as the photopolymerizable monomer, it is preferable to use the above-described copolymerizable monomer component such as the (meth)acrylic acid alkyl ester or the (meth)acrylic acid alkyl ester and the polar group-containing monomer, the polyfunctional monomer or oligomer.

The photopolymerization initiator is not particularly limited so long as it generates radicals by light such as ultraviolet rays (UV) and initiates photopolymerization, and the photopolymerization initiator can be appropriately selected from known or commonly used photopolymerization initiators and used. Examples of the photopolymerization initiator include benzoin ether-based photopolymerization initiators, acetophenone-based photopolymerization initiators, α-ketol-based photopolymerization initiators, photoactive oxime-based photopolymerization initiators, benzoin-based photopolymerization initiators, benzil-based photopolymerization initiators, benzophenone-based photopolymerization initiators, ketal-based photopolymerization initiators, and thioxanthone-based photopolymerization initiators.

Specifically, examples of the benzoin ether-based photopolymerization initiators include benzoin methyl ether, benzoin ethyl ether, benzoin propyl ether, benzoin isopropyl ether, benzoin isobutyl ether, 2,2-dimethoxy-1,2-diphenylethan-1-one, and anisole methyl ether. Examples of the acetophenone-based photopolymerization initiators include 2,2-diethoxyacetophenone, 2,2-dimethoxy-2-phenylacetophenone, 1-hydroxycyclohexyl phenyl ketone, 4-phenoxydichloroacetophenone, and 4-t-butyldichloroacetophenone. Examples of the α-ketol-based photopolymerization initiators include 2-methyl-2-hydroxypropiophenone and 1-[4-(2-hydroxyethyl)phenyl]-2-hydroxy-2-methylpropan-1-one. Examples of the photoactive oxime-based photopolymerization initiators include 1-phenyl-1,1-propanedione-2-(o-ethoxycarbonyl)-oxime. Examples of the benzoin-based photopolymerization initiators include benzoin. Examples of the benzil-based photopolymerization initiators include benzil. Examples of the benzophenone-based photopolymerization initiators include benzophenone, benzoylbenzoic acid, 3,3′-dimethyl-4-methoxybenzophenone, polyvinylbenzophenone, and α-hydroxycyclohexyl phenyl ketone. Examples of the ketal-based photopolymerization initiators include benzil dimethyl ketal. Examples of the thioxanthone-based photopolymerization initiators include thioxanthone, 2-chlorothioxanthone, 2-methylthioxanthone, 2,4-dimethylthioxanthone, isopropylthioxanthone, 2,4-dichlorothioxanthone, 2,4-diethylthioxanthone, 2,4-diisopropylthioxanthone, and dodecylthioxanthone.

The amount of the photopolymerization initiator is not particularly limited and is, for example, in the range of 0.01 part by weight to 5 parts by weight, preferably 0.05 part by weight to 3 parts by weight based on 100 parts by weight of the total monomer components.

Moreover, as light for use in irradiation, for example, energy rays (radiation rays) such as visible rays, ultraviolet rays, and electron beams can be used and particularly, ultraviolet rays are suitable. A light irradiation means is not particularly limited and, in the case where light is ultraviolet rays, for example, high-pressure discharging lamps such as metal halide lamps and high-pressure mercury lamps, low-pressure discharging lamps such as black light and insect-catching fluorescent lamps, and the like can be employed. The illuminance at the liquid surface of the composition to be subjected to light irradiation is not particularly restricted but usually, is about 0.1 to 300 mW/cm², preferably 1 to 50 mW/cm². With regard to the temperature at the light irradiation, it is important that water contained in the water-supporting body in the photopolymerizable composition does not vaporize (boil), and the temperature is usually 15° C. or higher and lower than 100° C. (e.g., 20° C. to 95° C.), preferably about 40° C. to 95° C.

The degree of the prepolymerization (preliminary polymerization) at the preparation of the photopolymerizable prepolymer is preferably a degree that the resulting photopolymerizable prepolymer becomes a syrup having fluidity. The polymerization ratio is, for example, about 1% to 50%, preferably about 5% to 40%.

The content of the photopolymerizable prepolymer in the photopolymerizable composition is not particularly limited but is usually about 75% by weight to 97% by weight, preferably 80% by weight to 96% by weight, further preferably 85% by weight to 94% by weight.

Moreover, the content of the water-supporting body in the photopolymerizable composition is in the range of 3% by weight to 50% by weight, preferably 5% by weight to 30% by weight, further preferably 10% by weight to 20% by weight as is similar to the case of the pressure-sensitive adhesive composition constituting the water-supporting body-containing pressure-sensitive adhesive layer.

A surfactant may be added to the photopolymerizable composition. As the surfactant, there may be used various surfactants such as nonionic surfactants, anionic surfactants, cationic surfactants, and amphoteric surfactants. The surfactants can be used solely or two or more kinds thereof can be used in combination.

As the surfactant, nonionic surfactants can be suitably used. Examples of the nonionic surfactants (non-ionic surfactants) include ether-type nonionic surfactants such as polyoxyethylene alkylphenyl ethers (polyoxyethylene octylphenyl ether, polyoxyethylene nonylphenyl ether, polyoxyethylene dodecylphenyl ether, etc.), polyoxyethylene alkylallyl ethers, polyoxyethylene alkyl ethers (polyoxyethylene oleyl ether, polyoxyethylene lauryl ether, etc.), and polyoxyethylene polyoxypropylene block polymers; ester ether-type nonionic surfactants such as polyethylene glycol fatty acid esters (polyethylene glycol oleic acid esters, etc.), polyoxyethylene sorbitan fatty acid esters (polyoxyethylene sorbitan monopalmitic acid esters, etc.); ester-type nonionic surfactants such as glycerin fatty acid esters (glycerin monostearic acid esters, etc.), sorbitan fatty acid esters (sorbitan monostearic acid esters, etc.), and sucrose fatty acid esters (sucrose stearic acid esters, etc.); and alkanolamide-type nonionic surfactants such as fatty acid alkanolamides (lauric acid diethanolamide, etc.). Preferable nonionic surfactants include glycerin fatty acid esters and sorbitan fatty acid esters.

Moreover, as the nonionic surfactants, HLB (Hydrophile-Lipophile-Balance) is preferably less than 7, and is in the range of more preferably 3.5 to 6.8, further preferably 4.0 to 6.7, particularly preferably 5.5 to 6.6.

The amount of the surfactant in the photopolymerizable composition is usually about 0 to 10 parts by weight, preferably 0.2 to 5 parts by weight, further preferably 0.5 to 3 parts by weight.

Into the photopolymerizable composition, the above-described photopolymerizable monomer (e.g., the above-described (meth)acrylic acid alkyl ester, polar group-containing monomer, polyfunctional monomer or oligomer, etc.) and the photopolymerization initiator may be further added. The polyfunctional monomer or oligomer may be used at the preparation of the photopolymerizable prepolymer but is preferably added after the preparation of the photopolymerizable prepolymer. Moreover, into the photopolymerizable monomer composition, if necessary, additives as exemplified in the explanation part of the above-described water-supporting body-containing pressure-sensitive adhesive layer, a catalyst for promoting the dissociation of the blocked crosslinking agent, and a component capable of forming a polymer through a reaction with the crosslinking agent may be added. These components may be added at the preparation of the photopolymerizable prepolymer.

The photopolymerizable composition can be prepared by mixing and dispersing the above-described individual components (photopolymerizable prepolymer, water-supporting body, crosslinking agent, surfactant, additives, etc.) so as to form a homogeneous or almost homogeneous mixture. In this regard, the crosslinking agent and the like may be added at the preparation of the photopolymerizable prepolymer. The photopolymerizable composition preferably has an appropriate viscosity suitable for coating work. The viscosity of the photopolymerizable composition can be controlled by controlling the polymerization ratio of the photopolymerizable prepolymer or by blending various polymers such as an acrylic rubber and a thickening additive. A desirable viscosity of the photopolymerizable composition can be selected from the range of 5 Pa·s to 50 Pa·s, preferably 10 Pa·s to 40 Pa·s as viscosity determined under conditions of a rotor of No. 5 rotor, a rotation number of 10 rpm, and a measurement temperature of 30° C. using a BH viscometer. When the viscosity of the photopolymerizable composition (BH viscometer; rotor: No. 5 rotor, rotation number: 10 rpm, measurement temperature: 30° C.) is less than 5 Pa·s, the liquid flows over when applied on the separator or the base material. On the other hand, when the viscosity exceeds 50 Pa·s, the viscosity is too high and there is a case where the application becomes difficult.

The water-supporting body-containing pressure-sensitive adhesive layer can be formed by applying the thus obtained photopolymerizable composition on the separator or the base material and curing the composition through light irradiation. The method of applying the photopolymerizable composition on the separator or the base material is not particularly limited and is appropriately selected from known methods using a roll coater, a bar coater, or a die coater, for example. At the irradiation with light, in order to avoid polymerization inhibition by oxygen, it is preferable to block oxygen by covering the surface of the sheet-shaped photopolymerizable composition layer formed by the application with a separator or the like. In this regard, as the separator or the base material on the light irradiation side, it is important to use one made of a material which transmits the light (particularly, ultraviolet rays) for use in the irradiation.

Incidentally, in the case where the water-supporting body-containing pressure-sensitive adhesive layer is formed by applying the photopolymerizable composition on the separator, the water-supporting body-containing pressure-sensitive adhesive layer can be formed by transcribing (transferring) the water-supporting body-containing pressure-sensitive adhesive layer on the separator to the base material.

The thickness of the water-supporting body-containing pressure-sensitive adhesive layer varies depending on the use application, the method for the use, and the like but is, for example, about 1 to 50 μm, preferably 5 to 30 μm. When the thickness of the water-supporting body-containing pressure-sensitive adhesive layer is less than 1 μm, an absolute amount of the water-supporting body in the water-supporting body-containing pressure-sensitive adhesive layer decreases and thus there is a concern that easy peeling ability is impaired and also there is a case where the fixing and holding of the die-adhering layer becomes difficult. On the other hand, when the thickness of the water-supporting body-containing pressure-sensitive adhesive layer exceeds 50 μm, cohesion failure may occur in the water-supporting body-containing pressure-sensitive adhesive layer at peeling and the pressure-sensitive adhesive components may remain on the surface of the die-adhering layer, so that the surface of the die-adhering layer is apt to be fouled.

The water-supporting body-containing pressure-sensitive adhesive layer may be either a monolayer or a multilayer.

Incidentally, the pressure-sensitive adhesive sheet including the base material and the water-supporting body-containing pressure-sensitive adhesive layer may further include an intermediate layer between the base material and the water-supporting body-containing pressure-sensitive adhesive layer. Such an intermediate layer is not particularly limited and may be a layer corresponding to various intended purposes.

Moreover, in the pressure-sensitive adhesive sheet including the base material and the water-supporting body-containing pressure-sensitive adhesive layer, the water-supporting body-containing pressure-sensitive adhesive layer may be formed on at least one surface of the base material. For example, there may be mentioned a pressure-sensitive adhesive sheet in a form that the water-supporting body-containing pressure-sensitive adhesive layer is formed on one surface of the base material, a pressure-sensitive adhesive sheet in a form that the water-supporting body-containing pressure-sensitive adhesive layer is formed on each surface of the base material, a pressure-sensitive adhesive sheet in a form that the water-supporting body-containing pressure-sensitive adhesive layer is formed on one surface of the base material and a pressure-sensitive adhesive layer containing no water-supporting body (water-supporting body-non-containing pressure-sensitive adhesive layer) is formed on the other surface, and the like. In this regard, in the case where the water-supporting body-containing pressure-sensitive adhesive layer is formed on each surface of the base material, in the pressure-sensitive adhesive sheet fitted with the die-adhering layer, the die-adhering layer is formed on the water-supporting body-containing pressure-sensitive adhesive layer on at least one surface side of the base material. Moreover, in the case where the water-supporting body-containing pressure-sensitive adhesive layer is formed on each surface of the base material, it is sufficient that the water-supporting body-containing pressure-sensitive adhesive layer on at least one surface of the base material has the above-described constitutions or characteristics.

Incidentally, it is sufficient that water-supporting body-non-containing pressure-sensitive adhesive layer is a pressure-sensitive adhesive layer containing no water-supporting body. The pressure-sensitive adhesive for forming the water-supporting body-non-containing pressure-sensitive adhesive layer is not particularly limited and known or commonly used pressure-sensitive adhesives such as the pressure-sensitive adhesives exemplified as pressure-sensitive adhesives to be used in the water-supporting body-containing pressure-sensitive adhesive layer (e.g., acrylic pressure-sensitive adhesives, rubber-based pressure-sensitive adhesives, vinyl alkyl ether-based pressure-sensitive adhesives, silicone-based pressure-sensitive adhesives, polyester-based pressure-sensitive adhesives, polyamide-based pressure-sensitive adhesives, urethane-based pressure-sensitive adhesives, fluorine-based pressure-sensitive adhesives, styrene-diene block copolymer-based pressure-sensitive adhesives, creeping property-improvable pressure-sensitive adhesives, radiation ray-curable pressure-sensitive adhesives, etc.) can be used. These pressure-sensitive adhesives can be used solely or two or more kinds thereof can be used in combination. Moreover, in the pressure-sensitive adhesives for forming the water-supporting body-non-containing pressure-sensitive adhesive layer, for example, known or commonly used additives such as tackifiers, coloring agents, thickening agents, extenders, fillers, plasticizers, antiaging agents, surfactants, and crosslinking agents may be blended.

The thickness of the water-supporting body-non-containing pressure-sensitive adhesive layer may be, for example, 300 μm or less (e.g., 1 μm to 300 μm, preferably 5 μm to 100 μm). Incidentally, as the method of forming the water-supporting body-non-containing pressure-sensitive adhesive layer, known or commonly used methods of forming the pressure-sensitive adhesive layer (e.g., a method of application on the base material, a method of application on the separator to form the pressure-sensitive adhesive layer and subsequently transcribing it on the base material, etc.) can be utilized. In this regard, the water-supporting body-non-containing pressure-sensitive adhesive layer may be either a monolayer or a multilayer.

### (Pressure-Sensitive Adhesive Force)

With regard to the pressure-sensitive adhesive sheet (pressure-sensitive adhesive sheet constituted by the base material and the water-supporting body-containing pressure-sensitive adhesive layer) in the pressure-sensitive adhesive sheet fitted with the die-adhering layer, pressure-sensitive adhesive force before the heating treatment [i.e., pressure-sensitive adhesive force before the water contained in the water-supporting body is desorbed (eliminated) from the support (in a state of containing water-supporting body)] (temperature: 23° C., peeling angel: 15°, drawing rate: 300 mm/min) is suitably 1 N/10 mm width or more (e.g., 1 N/10 mm width to 10 N/10 mm width), further preferably 1.5 N/10 mm width to 10 N/10 mm width. Incidentally, the pressure-sensitive adhesive force of the pressure-sensitive adhesive sheet before the heating treatment is a value (N/10 mm width) measured by press-bonding a semiconductor wafer having a thickness of 0.6 mm to the die-adhering layer of the pressure-sensitive adhesive sheet fitted with the die-adhering layer at 40° C. (pressure: 1.47×10⁵ Pa, time: 1 minute) by a heat lamination method, subsequently allowing it to stand for 30 minutes under an atmosphere of 23° C., and, after standing, peeling the pressure-sensitive adhesive sheet at the interface between the pressure-sensitive adhesive layer and the die-adhering layer under conditions of a temperature of 23° C., a peeling angle of 15° and a drawing rate of 300 mm/min.

Moreover, with regard to the pressure-sensitive adhesive sheet in the pressure-sensitive adhesive sheet fitted with the die-adhering layer, pressure-sensitive adhesive force after the heating treatment [i.e., pressure-sensitive adhesive force after the water contained in the water-supporting body is desorbed (eliminated) from the support (in a state of containing a support remained due to the elimination of the water from the water-supporting body] (temperature: 23° C., peeling angel: 15°, drawing rate: 300 mm/min) is suitably 5 N/10 mm width or less (e.g., 0 N/10 mm width to 5 N/10 mm width), further preferably 4 N/10 mm width or less (e.g., 0.01 N/10 mm width to 4 N/10 mm width). The pressure-sensitive adhesive force after the heating treatment is, in particular, preferably 3 N/10 mm width or less (e.g., 0.01 N/10 mm width to 3 N/10 mm width), particularly 2 N/10 mm width or less (e.g., 0.01 N/10 mm width to 2 N/10 mm width). Incidentally, the pressure-sensitive adhesive force of the pressure-sensitive adhesive sheet after the heating treatment is a value (N/10 mm width) measured by press-bonding a semiconductor wafer having a thickness of 0.6 mm to the die-adhering layer of the pressure-sensitive adhesive sheet fitted with the die-adhering layer (pressure: 1.47×10⁵ Pa, time: 1 minute) by a heat lamination method, subsequently allowing it to stand under an atmosphere of 120° C. for 3 minutes and then under an atmosphere of 23° C. for 30 minutes, and, after standing, peeling the pressure-sensitive adhesive sheet at the interface between the pressure-sensitive adhesive layer and the die-adhering layer under conditions of a temperature of 23° C., a peeling angle of 15° and a drawing rate of 300 mm/min.

Therefore, the pressure-sensitive adhesive force (pressure-sensitive adhesive force before the heating treatment, pressure-sensitive adhesive force after the heating treatment) of the pressure-sensitive adhesive sheet in the pressure-sensitive adhesive sheet fitted with the die-adhering layer is a pressure-sensitive adhesive force of the water-supporting body-containing pressure-sensitive adhesive layer before or after the heating treatment and also a pressure-sensitive adhesive force against the die-adhering layer to which the semiconductor wafer has been attached (die-adhering layer in the semiconductor wafer with the die-adhering layer).

### Die-Adhering Layer

It is important that the die-adhering layer has a function of adhering and supporting a semiconductor wafer during processing of the semiconductor wafer (e.g., cut-processing thereof into a chip form) which has been press-bonded onto the die-adhering layer and a function of acting as an adhering layer of a processed body of the semiconductor wafer (e.g., a semiconductor chip cut into a chip form) to various carriers when the processed body of the semiconductor wafer is mounted. Particularly, as the die-adhering layer, it is important to have such adhesiveness that cut pieces do not fly during processing of the semiconductor wafer (e.g., processing such as cut-processing).

Such a die-adhering layer can have, for example, a constitution of only a single layer of the pressure-sensitive adhesive layer. Moreover, the die-adhering layer may be a multilayer of two or more layers with suitably combining thermoplastic resins different in glass transition temperature and thermosetting resins different in thermal curing temperature. Incidentally, since cutting water is used in the cutting step of the semiconductor wafer and water vapor generates from the pressure-sensitive adhesive layer during the peeling step using the product of the present invention, there is a case where the die-adhering layer absorbs moisture and the moisture content becomes a normal condition or more. When the die-adhering layer is adhered to a substrate or the like with such a high moisture content, water vapor is accumulated at an adhering interface in the stage of after-curing, and there is a case where lifting may occur. Therefore, by making the die-adhering layer have a constitution that a core material having a high moisture permeability is sandwiched with die-adhering layers, water vapor diffuses through the core material in the stage of after-curing and thus such a problem can be avoided. From such a viewpoint, the die-adhering layer may have a multi-layered structure in which the die-adhering layer is formed on one surface or each surface of the core material.

Examples of the core material include films (e.g., polyimide films, polyester films, polyethylene terephthalate films, polyethylene naphthalate films, polycarbonate films, etc.), resin substrates reinforced with a glass fiber or a plastic nonwoven fiber, a silicon substrates, and glass substrates.

The die-adhering layer according to the invention is preferably constituted by a resin composition containing an epoxy resin. In the resin composition, the ratio of the epoxy resin can be appropriately selected from the range of 5% by weight or more, preferably 7% by weight or more, more preferably 9% by weight or more based on the whole amount of the polymer components. An upper limit of the ratio of the epoxy resin is not particularly limited and may be 100% by weight or less, preferably 50% by weight or less, more preferably 40% by weight or less based on the whole amount of the polymer components.

The epoxy resin is preferable from the viewpoint that the content of ionic impurities and the like which corrode a semiconductor element is small. The epoxy resin is not particularly restricted as long as it is generally used as an adhesive composition. For example, a bifunctional epoxy resin or a polyfunctional epoxy resin such as a bispehnol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a biphenyl type epoxy resin, a naphthalene type epoxy resin, a fluorene type epoxy resin, a phenol novolak type epoxy resin, an o-cresol novolak type epoxy resin, a trishydroxyphenylmethane type epoxy resin, and a tetraphenylolethane type epoxy resin, or an epoxy resin such as a hydantoin type epoxy resin, a trisglycidylisocyanurate type epoxy resin or a glycidylamine type epoxy resin may be used. The epoxy resins can be used solely or two or more kinds thereof can be used in combination.

As the epoxy resin, among those exemplified in the above, a novolak type epoxy resin, a biphenyl type epoxy resin, a trishydroxyphenylmethane type epoxy resin, and a tetraphenylolethane type epoxy resin are particularly preferable. This is because these epoxy resins have high reactivity with a phenol resin as a curing agent and are superior in thermal resistance and the like.

Moreover, other thermosetting resins or thermoplastic resins can be used in combination in the die-adhering layer according to needs. Examples of the thermosetting resins include phenol resins, amino resins, unsaturated polyester resins, polyurethane resins, silicone resins, and thermosetting polyimide resins. These thermosetting resins can be used solely or two or more kinds thereof can be used in combination. Here, a phenol resin is preferable as a curing agent for the epoxy resin.

Furthermore, the phenol resin acts as a curing agent for the epoxy resin, and examples thereof include novolak type phenol resins such as phenol novolak resins, phenol aralkyl resins, cresol novolak resins, tert-butylphenol novolak resins, and nonylphenol novolak resins; resol type phenol resins; and polyhydroxystyrenes such as poly-p-hydroxystyrene. They can be used solely or two or more kinds thereof can be used in combination. Among these phenol resins, phenol novolak resins and phenol aralkyl resins are particularly preferable. This is because connection reliability of the semiconductor device can be improved.

The mixing ratio of the epoxy resin to the phenol resin is preferably made, for example, such that the hydroxyl group in the phenol resin becomes 0.5 to 2.0 equivalents per equivalent of the epoxy group in the epoxy resin component. It is more preferably 0.8 to 1.2 equivalents. That is, when the mixing ratio falls outside of the range, a sufficient curing reaction does not proceed, and the characteristics of the epoxy resin cured product is apt to deteriorate.

Examples of the thermoplastic resins include natural rubber, butyl rubber, isoprene rubber, chloroprene rubber, ethylene-vinyl acetate copolymers, ethylene-acrylic acid copolymers, ethylene-acrylate ester copolymers, polybutadiene resin, polycarbonate resins, thermoplastic polyimide resins, polyamide resins such as 6-Nylon and 6,6-Nylon, phenoxy resins, acrylic resins, saturated polyester resins such as PET and PBT, polyamideimide resins, and fluorinated resins. These thermoplastic resins can be used solely or two type or more can be used in combination. Among these thermoplastic resins, acrylic resins are particularly preferable, wherein the ionic impurities are less, the heat resistance is high, and reliability of the semiconductor element can be secured.

The acrylic resins are not particularly restricted, and examples thereof include polymers containing one or more types of acrylic or methacrylic acid esters having a straight chain or branched alkyl group having 30 or less carbon atoms, particularly 4 to 18 carbon atoms as component(s). Examples of the alkyl group include a methyl group, an ethyl group, a propyl group, an isopropyl group, an n-butyl group, a t-butyl group, an isobutyl group, a pentyl group, an isopentyl group, a hexyl group, a heptyl group, a 2-ethylhexyl group, an octyl group, an isooctyl group, a nonyl group, an isononyl group, a decyl group, an isodecyl group, an undecyl group, a dodecyl group (lauryl group), a tridecyl group, a tetradecyl group, a stearyl group, and an octadecyl group.

Moreover, other monomers for forming the acrylic resins (monomers other than the acrylic or methacrylic acid esters having 30 or less carbon atoms) are not particularly restricted, and examples thereof include carboxyl group-containing monomers such as acrylic acid, methacrylic acid, carboxylethyl acrylate, carboxylpentyl acrylate, itaconic acid, maleic acid, fumaric acid, and crotonic acid; acid anhydride monomers such as maleic anhydride and itaconic anhydride; hydroxyl group-containing monomers such as 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydecyl(meth)acrylate, 12-hydroxylauryl(meth)acrylate, and (4-hydroxymethylcyclohexyl)-methyl acrylate; sulfonic acid group-containing monomers such as styrenesulfonic acid, allylsulfonic acid, 2-(meth)acrylamido-2-methylpropanesulfonic acid, (meth)acrylamidopropanesulfonic acid, sulfopropyl(meth)acrylate, and (meth)acryloyloxynaphthalenesulfonic acid; and phosphoric acid group-containing monomers such as 2-hydroxyethylacryloyl phosphate.

In the invention, the thermoplastic resin (particularly, an acrylic resin) can be used in a ratio of less than 90% by weight, for example, 1 to 90% by weight based on the whole amount of the polymer components including an epoxy resin. The ratio of the thermoplastic resin such as an acrylic resin is preferably 20% by weight to 85% by weight, and more preferably 40% by weight to 80% by weight based on the whole amount of the polymer components.

In order to perform the crosslinking in the die-adhering layer (particularly, adhesive layer composed of a resin composition containing an epoxy resin) in advance, a polyfunctional compound that reacts with a functional group in the end of molecular chain of the polymer is preferably added as a crosslinking agent at the production. Thereby, the adhesive characteristic under high temperature can be improved, and the improvement of the thermal resistance can be attained.

Other additives can be appropriately mixed in the die-adhering layer (adhesive layer composed of a resin composition containing an epoxy resin) according to needs. Examples of the other additives include flame retardants, silane coupling agents, and ion trapping agents as well as coloring agents, extenders, fillers, antiaging agents, antioxidants, surfactants, and crosslinking agents. Examples of the flame retardants include antimony trioxide, antimony pentoxide, and brominated epoxy resins. The flame retardants can be used solely or two or more types can be used in combination. Examples of the silane coupling agents include β-(3,4-epoxycyclohexyl)ethyltrimethoxysilane, γ-glycidoxypropyltrimethoxysilane, and γ-glycidoxypropylmethyldiethoxysilane. The silane coupling agents can be used solely or two or more kinds thereof can be used in combination. Examples of the ion trapping agents include hydrotalcites and bismuth hydroxide. The ion trapping agents can be used solely or two or more kinds thereof can be used in combination.

Incidentally, the die-adhering layer can be made to have an antistatic function. Thereby, the circuit can be prevented from breaking down due to the generation of electrostatic energy during adhesion and peeling thereof and charging of a workpiece (a semiconductor wafer, etc.) by the electrostatic energy. Imparting of the antistatic function can be performed by an appropriate method such as a method of adding an antistatic agent or a conductive substance to the base material, the water-supporting body-containing pressure-sensitive adhesive layer, or the die-adhering layer or a method of providing a conductive layer composed of a charge-transfer complex, a metal film, or the like onto the base material. As these methods, a method that hardly generates an impurity ion having a fear of changing quality of the semiconductor wafer is preferable. Examples of the conductive substance (conductive filler) to be blended for the purpose of imparting conductivity, improving thermal conductivity, and the like include sphere-shaped, needle-shaped, flake-shaped powders of metals such as silver, aluminum, gold, copper, nickel, and a conductive alloy; metal oxides such as alumina; amorphous carbon black, and graphite. However, the die-adhering layer is preferably non-conductive from the viewpoint of no electric leakage.

The thickness of the die-adhering layer is not particularly restricted but is, for example, about 5 μm to 100 μm, and preferably about 5 μm to 50 μm.

Form of Pressure-Sensitive Adhesive Sheet Fitted with Die-Adhering layer

The pressure-sensitive adhesive sheet fitted with the die-adhering layer according to the invention may have a form of a double-sided pressure-sensitive adhesive sheet wherein both surfaces are adhesive surfaces but preferably has a form of an adhesive sheet wherein only one surface is an adhesive surface. Therefore, the pressure-sensitive adhesive sheet fitted with the die-adhering layer is suitably a pressure-sensitive adhesive sheet fitted with the die-adhering layer having such a form that the die-adhering layer is laminated on the water-supporting body-containing pressure-sensitive adhesive layer in the pressure-sensitive adhesive sheet having a constitution that the water-supporting body-containing pressure-sensitive adhesive layer is formed on one surface of the base material.

Moreover, the pressure-sensitive adhesive sheet fitted with the die-adhering layer may be formed in a form that it is wound as a roll or may be formed in a form that the sheet is laminated. For example, in the case where the sheet has the form that it is wound as a roll, the sheet is wound as a roll in a state that the die-adhering layer is protected by a separator, that is, the sheet is wound as a roll in a state that the sheet is constituted by a base material, a water-supporting body-containing pressure-sensitive adhesive layer formed on one surface of the base material, a die-adhering layer laminated on the water-supporting body-containing pressure-sensitive adhesive layer, and a separator formed on the die-adhering layer, whereby the sheet can be prepared as a pressure-sensitive adhesive sheet fitted with the die-adhering layer in a state or form that it is wound as a roll. In this regard, the pressure-sensitive adhesive sheet fitted with the die-adhering layer in the state or form that it is wound as a roll may be constituted by a base material, a water-supporting body-containing pressure-sensitive adhesive layer formed on one surface of the base material, a die-adhering layer laminated on the water-supporting body-containing pressure-sensitive adhesive layer, and a releasably treated layer (rear surface treated layer) formed on the other surface of the base material.

As above, the pressure-sensitive adhesive sheet fitted with the die-adhering layer of the invention can have a form of a sheet-shape, a tape-shape, or the like.

### Separator

In the invention, as the separator (release liner), a commonly used release paper or the like can be used. The separator is used as a protective material of the die-adhering layer and is peeled off at the time when the pressure-sensitive adhesive sheet fitted with the die-adhering layer is pasted to the adherend. The separator is not necessarily provided. As the separator, for example, base materials having a release layer, such as plastic films and papers whose surface is treated with a releasing agent such as silicone-based one, long-chain alkyl-based one, fluorine-based one, or molybdenum sulfide; low adhesive base materials composed of fluorine-based polymers such as polytetrafluoroethylene, polychiorotrifluoroethylene, polyvinyl fluoride, polyvinylidene fluoride, tetrafluoroethylene-hexafluoropropylene copolymers, and chlorofluoroethylene-vinylidene fluoride copolymers; and low adhesive base materials composed of non-polar polymers such as olefinic resins (e.g., polyethylene, polypropylene, etc.) can be used. In this regard, it is also possible to utilize the separator as a base material for supporting the die-adhering layer (particularly, a supporting base material at the time when the die-adhering layer is transcribed onto the pressure-sensitive adhesive sheet for lamination).

Incidentally, the separator can be formed by known or commonly used methods. Moreover, the thickness of the separator is not particularly limited.

### Semiconductor Wafer

The semiconductor wafer is not particularly limited as long as it is a known or commonly used semiconductor wafer and can be appropriately selected from semiconductor wafers made of various materials and used. In the invention, as the semiconductor wafer, a silicon wafer can be suitably used.

### Producing Process of Semiconductor Device

The process for producing the semiconductor device of the invention is not particularly limited as long as it is a process for producing a semiconductor device using the above-described pressure-sensitive adhesive sheet fitted with the die-adhering layer. In the invention, a process for producing the semiconductor device including the following steps is suitable:

a step (mounting step) of attaching a semiconductor wafer to the die-adhering layer of the laminated film having the water-supporting body-containing pressure-sensitive adhesive layer;

a step (dicing step) of subjecting the semiconductor wafer having the laminated film attached thereto to a cut-processing treatment after the mounting step;

a step (picking-up step) of peeling semiconductor chip(s) formed by the cut-processing treatment from the water-supporting body-containing pressure-sensitive adhesive layer together with the die-adhering layer after the dicing step; and

a step (die-bonding step) of adhering the semiconductor chip fitted with the die-adhering layer to an adherend after the picking-up step.

Specifically, the semiconductor device can be produced using the pressure-sensitive adhesive sheet fitted with the die-adhering layer according to the invention after appropriate peeling of the separator arbitrarily provided on the die-adhering layer as follows. First, a semiconductor wafer is press-bonded and attached on the die-adhering layer in the pressure-sensitive adhesive sheet fitted with the die-adhering layer (i.e., the laminated film having the water-supporting body-containing pressure-sensitive adhesive layer), and it is fixed by adhesion and holding (mounting step). The present step is performed while pressing with a pressing means such as a pressing roll.

Next, the dicing (cut-processing) of the semiconductor wafer is performed by subjecting the semiconductor wafer having the laminated film attached thereto to the cut-processing treatment (dicing step). Thereby, the semiconductor wafer is cut into a prescribed size and individualized (is formed into small pieces) to produce a semiconductor chip(s). The dicing is performed following a usual method from the circuit face side of the semiconductor wafer, for example. Moreover, in the present step, for example, there can be adopted a cutting method called full-cut that forms a slit into the pressure-sensitive adhesive sheet. The dicing apparatus used in the present step is not particularly restricted, and a conventionally known apparatus can be used. Furthermore, since the semiconductor wafer is adhered and fixed by the pressure-sensitive adhesive sheet fitted with the die-adhering layer, chip crack and chip fly can be suppressed, and at the same time, the damage of the semiconductor wafer can be also suppressed. In this regard, in the case where the die-adhering layer is formed of a resin composition containing an epoxy resin, even when it is cut by dicing, the generation of adhesive extrusion at the adhesive layer of the die-adhering layer is suppressed or prevented in the cut surface. As a result, re-attachment (blocking) of the cut surfaces each other can be suppressed or prevented and thus the picking-up to be mentioned below can be further conveniently performed.

In the case where the pressure-sensitive adhesive sheet fitted with the die-adhering layer is expanded, the expansion can be performed using a conventionally known expanding apparatus. The expanding apparatus has a doughnut-shaped outer ring capable of pushing the pressure-sensitive adhesive sheet fitted with the die-adhering layer downward through a dicing ring and an inner ring which has a diameter smaller than the outer ring and supports the pressure-sensitive adhesive sheet fitted with the die-adhering layer. By the expanding step, it is possible to prevent the damage of adjacent semiconductor chips through their contact with each other in the picking-up step to be mentioned below.

In order to recover a semiconductor chip that is adhered and fixed to the pressure-sensitive adhesive sheet fitted with the die-adhering layer, picking-up of the semiconductor chip is performed (picking-up step). Namely, the semiconductor chip formed by the cut-processing treatment is peeled from the water-supporting body-containing pressure-sensitive adhesive layer together with the die-adhering layer to pick up the semiconductor chip. Here, in the picking-up, for generating water vapor from the water-supporting body in the water-supporting body-containing pressure-sensitive adhesive layer, the laminated film having the wafer mounted thereon is subjected to a heating treatment. The heating treatment can be performed by an appropriate method such as a method using a hot-air dryer, a method using a hot plate, or a method utilizing infrared ray irradiation. The temperature at the heating treatment may be a temperature equal to or higher than the temperature at which water contained in the water-supporting body boils (100° C. or higher under normal pressure). By the heating treatment step, water contained in the water-supporting body in the water-supporting body-containing pressure-sensitive adhesive layer of the pressure-sensitive adhesive sheet spouts as water vapor from the surface of the water-supporting body-containing pressure-sensitive adhesive layer and presses the contact surface with the die-adhering layer, so that the semiconductor chip can be easily peeled off at the interface between the water-supporting body-containing pressure-sensitive adhesive layer and the die-adhering layer of the pressure-sensitive adhesive sheet and thus it is possible to obtain the semiconductor chip fitted with the die-adhering layer without damage. As mentioned above, the picking-up of the semiconductor chip fitted with the die-adhering layer is performed at the time when the pressure-sensitive adhesive force between the die-adhering layer and the water-supporting body-containing pressure-sensitive adhesive layer is sufficiently lowered. The method for the picking-up is not particularly limited and hitherto known methods can be adopted. For example, there may be mentioned a method of pushing up the individual semiconductor chips from the base material side of the pressure-sensitive adhesive sheet with a needle and picking up the pushed semiconductor chips with a picking-up apparatus. In the laminated film of the invention, since a good peeling ability between the die-adhering layer and the water-supporting body-containing pressure-sensitive adhesive layer is achieved by the heating treatment, the picking-up can be performed with reducing a yield ratio by lowering a protrusion degree of the needle or decreasing the number of the needles.

The semiconductor chip (semiconductor chip fitted with the die-adhering layer) picked up is adhered and fixed to an adherend through the die-adhering layer interposed therebetween (die bonding step). The adherend has been mounted on a heat block. Examples of the adherend include a lead frame, a TAB film, a substrate, and a semiconductor chip separately produced. The adherend may be a deformable adherend that is easily deformed, or may be a non-deformable adherend (such as a semiconductor wafer) that is difficult to deform, for example.

A conventionally known substrate can be used as the substrate. Moreover, a metal lead frame such as a Cu lead frame or a 42 Alloy lead frame and an organic substrate composed of glass epoxy, BT (bismaleimide-triazine), or a polyimide can be used as the lead frame. However, the invention is not restricted to the above, and includes a circuit substrate that can be used after mounting a semiconductor element and electrically connecting with the semiconductor element.

In the case where the die-adhering layer is formed of a resin composition containing a thermosetting resin such as an epoxy resin, the adhesive force is enhanced by heat-curing and thus the semiconductor chip can be adhered and fixed onto the adherend through the die-adhering layer interposed therebetween to improve the degree of the heat resistance. In this regard, a product in which the semiconductor chip is adhered and fixed onto a substrate or the like through a semiconductor wafer-pasting part interposed therebetween can be subjected to a reflow step. Thereafter, wire bonding is performed by electrically connecting the tip of a terminal part (inner lead) of the substrate and an electrode pad on the semiconductor chip with a bonding wire, and furthermore, the semiconductor chip is sealed with a sealing resin, followed by subjecting the sealing resin to after-curing. Thereby, the semiconductor device according to the present embodiment is manufactured.

### Examples

The following will illustratively describe preferred examples of the invention in detail. However, the materials, the mixing amount, and the like described in these examples are not intended to limit the scope of the invention to only those unless otherwise stated, and they are merely explanatory examples. Moreover, part in each example is a weight standard unless otherwise stated.

Incidentally, the polymerization ratio of the photopolymerizable prepolymer was calculated according to the following equation based on weight measurement of obtained syrup before and after drying, the drying of the syrup being performed at 130° C. for 3 hours to remove monomers.

Polymerization Ratio (% by weight)=(Weight after Drying/Weight before Drying)×100

### Example 1

### (Manufacture of Pressure-Sensitive Adhesive Sheet)

96.8 parts by weight of 2-ethylhexyl acrylate (sometimes refers to as “2EHA”), 3.2 parts by weight of 2-hydroxyethyl acrylate (sometimes refers to as “HEA”), and 0.1 part by weight of a photopolymerization initiator (product name “Irgacure 651” manufactured by Ciba Specialty Chemicals) based on the total monomer components were mixed and stirred and nitrogen gas was introduced therein to remove dissolved oxygen. The mixed solution was subjected to ultraviolet ray (UV) irradiation at a temperature of 23° C. [an ultraviolet ray irradiation apparatus: product name “SPOT CURE SP-7] manufactured by Ushio, Inc., liquid surface illuminance: 3 mW/cm²]. After 3 minutes, the irradiation was stopped and, after cooled to about 30° C., the resulting syrup (a photopolymerizable prepolymer) was taken out. The viscosity of the syrup was 24.3 Pa·s (BH viscometer, No. 5 rotor, 10 rpm, 30° C.) and the polymerization ratio was 10%.

To 100 parts by weight of the syrup were added 1 part by weight of trimethylolpropane triacrylate (product name “Biscoat #295” manufactured by Osaka Organic Chemical Industry Ltd.), 0.5 part by weight of a surfactant (product name “EMULGEN 102GK”, HLB=6.3, Kao Corporation), 5 parts by weight of a water-supporting body (obtained by pulverizing 10 g of a product name “Silica gel PP” manufactured by Shin-Etsu Kasei Kogyo K.K. in a pulverizer and classifying the pluverized one; average particle diameter: 15 μm, water content: 80% by weight), and 7 parts by weight of a crosslinking agent (product name “Takenate WB700” manufactured by Mitsui Chemicals Polyurethanes, Inc.) and the whole was stirred to obtain a photopolymerizable composition.

The resulting photopolymerizable composition was applied on the releasably treated surface of a polyethylene terephthalate film whose one surface had been releasably treated (release liner) to form a photopolymerizable composition layer. Then, a polyolefin film (base material; thickness: 100 μm) whose one surface had been subjected to a surface treatment (corona treatment) was laminated on the photopolymerizable composition layer so that the surface-treated face of the polyolefin film came into contact with the photopolymerizable composition layer. From the release liner side of the laminate, an ultraviolet ray (UV) was applied at a temperature of 23° C. by black light having a maximum illuminance of about 4 mW/cm² for 3 minutes to cure the photopolymerizable composition, thereby a pressure-sensitive adhesive sheet having a layer structure of a release liner (thickness: 50 μm)/water-supporting body-containing pressure-sensitive adhesive layer (thickness: 30 μm)/base material (thickness: 100 μm) being manufactured.

### (Manufacture of Die-Adhering Layer and Laminated Film)

59 parts by weight of an epoxy resin 1 (product name “EPICOAT 1004” manufactured by Japan Epoxy Resins (JER) Co., Ltd.), 53 parts by weight of an epoxy resin 2 (product name “EPICOAT 827” manufactured by Japan Epoxy Resins (JER) Co., Ltd.), 121 parts by weight of a phenol resin (product name “MILEX XLC-4L” manufactured by Mitsui Chemicals, Inc.), 222 parts by weight of spherical silica (product name “SO-25R” manufactured by Admatechs Co., Ltd.) based on 100 parts by weight of an acrylic acid ester-based polymer (product name “PARACRON W-197CM” manufactured by Negami Chemical Industrial Co., Ltd.) containing ethyl acrylate-methyl methacrylate as a main component were dissolved into methyl ethyl ketone to prepare a solution of an adhesive composition having a solid concentration of 23.6% by weight.

The solution of the adhesive composition was applied onto a polyethylene terephthalate film on which a release treatment had been performed, thereby a die-adhering layer sheet having a thickness of 25 μm being obtained. The release liner of the above-described pressure-sensitive adhesive sheet was peeled off and the above-described die-adhering layer was transcribed onto the water-supporting body-containing pressure-sensitive adhesive layer to obtain a pressure-sensitive adhesive layer fitted with a die-adhering layer according to the present Example.

### Examples 2 to 4

Pressure-sensitive adhesive sheets fitted with a die-adhering layer (laminated films) were manufactured in the same manner as in Example 1 except that the composition of the photopolymerizable composition was changed to the composition (kind and content of monomer components) shown in Table 1. Incidentally, in Example 2, the amount of the crosslinking agent (product name “Takenate WB700” manufactured by Mitsui Chemicals Polyurethanes, Inc.) was changed to 6.5 parts by weight based on 100 parts by weight of the syrup.

### Comparative Example 1

A pressure-sensitive adhesive sheet fitted with a die-adhering layer (laminated film) was manufactured in the same manner as in Example 1 except that the water-supporting body was not used (i.e., except that no water-supporting body was contained in the pressure-sensitive adhesive composition of the pressure-sensitive adhesive sheet).

### Comparative Example 2

A pressure-sensitive adhesive sheet fitted with a die-adhering layer (laminated film) was manufactured in the same manner as in Example 1 except that silica gel supporting no water or almost no water [dry silica gel obtained by pulverizing 10 g of a product name “Silica gel PP” manufactured by Shin-Etsu Kasei Kogyo K.K. in a pulverizer, classifying the pulverized one (average particle diameter: 15 μm), and then drying the classified one at a temperature of 130° C. for 1 hour in a hot-air dryer] was used instead of the water-supporting body shown in Example 1 (water-supporting silica gel in a ratio of a water content of 80% by weight).

### Comparative Example 3

A pressure-sensitive adhesive sheet fitted with a die-adhering layer (laminated film) was manufactured in the same manner as in Example 1 except that the crosslinking agent (product name “Takenate WB700” manufactured by Mitsui Chemicals Polyurethanes, Inc.) was not used and the amount of the trimethylolpropane acrylate (product name, manufactured by Daicel-Cytec Company Ltd.) was changed to 0.01 part by weight.

TABLE 1

| | | | | | | Pressure-sensitive | Pressure-sensitive | | |
|---|---|---|---|---|---|---|---|---|---|
| | Water- | Gel | Composition | | | adhesive force | adhesive force | Picking-up | Fouling |
| | supporting | fraction | [% by weight (mol %)] | | | before heating | after heating | success | preventive |
| | body | (% by weight) | 2EHA | BA | HEA | (N/10 mm) | (N/10 mm) | rate (%) | property |
| Example 1 | Presence | 97 | 96.8 (95) | | 3.2 (5) | 1.30 | 0.05 | 100 | Absence of |
| | | | | | | | | | fouling |
| Example 2 | Presence | 92 | 96.8 (95) | | 3.2 (5) | 1.35 | 0.07 | 100 | Absence of |
| | | | | | | | | | fouling |
| Example 3 | Presence | 97 | 64.0 (55) | 32.4 (40) | 3.6 (5) | 2.80 | 0.80 | 100 | Absence of |
| | | | | | | | | | fouling |
| Example 4 | Presence | 96 | | 95.4 (95) | 4.6 (5) | 3.20 | 2.30 | 90 | Absence of |
| | | | | | | | | | fouling |
| Comparative | Absence | 97 | 96.8 (95) | | 3.2 (5) | 1.43 | 4.50 | 0 | Absence of |
| Example 1 | | | | | | | | | fouling |
| Comparative | Absence (dry | 97 | 96.8 (95) | | 3.2 (5) | 1.32 | 4.60 | 0 | Absence of |
| Example 2 | silica gel) | | | | | | | | fouling |
| Comparative | Presence | 55 | 96.8 (95) | | 3.2 (5) | 3.50 | 4.70 | 5 | Presence of |
| Example 3 | | | | | | | | | fouling |

Incidentally, meanings of the abbreviations described in Table 1 are as follows.

2EHA: 2-ethylhexyl acrylate

BA: n-butyl acrylate

HEA: 2-hydroxyethyl acrylate

Moreover, in the columns of Composition in Table 1, the unit of the values in the upper column is % by weight based on the whole amount of monomer components and the unit of the values in parenthesis in the lower column is mol % (% by mol) based on the whole amount of monomer components.

### (Evaluation)

With regard to each of the pressure-sensitive adhesive sheets fitted with a die-adhering layer (laminated films) manufactured in Examples 1 to 4 and Comparative Examples 1 to 3, a gel fraction of the pressure-sensitive adhesive layer, pressure-sensitive adhesive force before heating, and pressure-sensitive adhesive force after heating were measured by the following measurement methods and also a picking-up property and a fouling preventive property were evaluated by the following evaluation methods. The results were shown in Table 1.

### (Measurement Method of Gel Fraction)

About 0.1 g was sampled from the pressure-sensitive adhesive layer (not subjected to a heating treatment for generating water vapor) of the pressure-sensitive adhesive sheet in each of the pressure-sensitive adhesive sheets fitted with a die-adhering layer and was precisely weighed (Sample Weight). After wrapped with a mesh sheet (manufactured with Teflon (registered trade mark)), the sample was immersed in about 50 ml of toluene at room temperature for 1 week. Thereafter, a solvent-insoluble content (a content in the mesh sheet) was taken out of the toluene and dried at 130° C. for about 2 hours after placed in a dryer, the solvent-insoluble content was weighed after drying (Weight after Immersion and Drying), and a gel fraction (% by weight) was calculated according to the following equation (a). Incidentally, the measurement results of the gel fraction are shown in the column of “Gel fraction (% by weight)” in Table 1.

Gel Fraction (% by weight)=[(Weight after Immersion and Drying)/(Sample Weight)]×100 (a)

(Measurement Method of Pressure-Sensitive Adhesive Force before Heating)

Each of the pressure-sensitive adhesive sheets fitted with a die-adhering layer was cut into a size having a width of 10 mm and a length of 10 cm and, after the separator was peeled off, the exposed surface of the die-adhering layer and a semiconductor wafer having a thickness of 0.6 mm were press-bonded at a temperature of 40° C. by a heat lamination method. After the press-bonding, the sheet was allowed to stand at a temperature of 23° C. for 30 minutes. After standing, the pressure-sensitive adhesive sheet was peeled off under conditions of a temperature of 23° C. and a humidity of 60% RH under conditions of a peeling rate (drawing rate) of 300 mm/min and a peeling angle of 15° using a tensile testing machine (product name “Autograph AG-IS” manufactured by Shimadzu Corporation) and a maximum load at the peeling (a maximum value of the load excluding a peak top at the initial stage of the measurement) was determined, the maximum load being regarded as peeling pressure-sensitive adhesive force between the pressure-sensitive adhesive layer and the die-adhering layer to determine pressure-sensitive adhesive force (N/10 mm width) of the pressure-sensitive adhesive layer of the pressure-sensitive adhesive sheet. The measured results of the pressure-sensitive adhesive force are shown in the column of “Pressure-sensitive adhesive force before heating (N/10 mm)” in Table 1.

(Measurement Method of Pressure-Sensitive Adhesive Force after Heating)

Each of the pressure-sensitive adhesive sheets fitted with a die-adhering layer was cut into a size having a width of 10 mm and a length of 10 cm and, after the separator was peeled off, the exposed surface of the die-adhering layer and a semiconductor wafer having a thickness of 0.6 mm were press-bonded at a temperature of 40° C. by a heat lamination method. After the press-bonding, the sheet was allowed to stand at a temperature of 23° C. for 30 minutes. Then, it was subjected to a heating treatment at a temperature of 120° C. for 3 minutes in a hot-air drier. After the heating treatment, the pressure-sensitive adhesive sheet was peeled off under conditions of a temperature of 23° C. and a humidity of 60% RH under conditions of a peeling rate (drawing rate) of 300 mm/min and a peeling angle of 15° using a tensile testing machine (product name “Autograph AG-IS” manufactured by Shimadzu Corporation) and a maximum load at the peeling (a maximum value of the load excluding a peak top at the initial stage of the measurement) was determined, the maximum load being regarded as the peeling pressure-sensitive adhesive force between the pressure-sensitive adhesive layer and the die-adhering layer to determine pressure-sensitive adhesive force (N/10 mm width) of the pressure-sensitive adhesive layer of the pressure-sensitive adhesive sheet. The measured results of the pressure-sensitive adhesive force are shown in the column of “Pressure-sensitive adhesive force after heating (N/10 mm)” in Table 1.

### (Evaluation Method of Picking-Up Property)

A semiconductor wafer having a thickness of 0.075 mm and a diameter of 8 inch was press-bonded on the die-adhering layer of each of the pressure-sensitive adhesive sheets fitted with a die-adhering layer (laminated films) at a temperature of 40° C. by a thermal lamination method, and further the semiconductor wafer was diced into a chip of 10 mm square by means of a rotary round blade. The dicing conditions are as shown below. Then, the semiconductor chips obtained by cutting (dicing) were subjected to a heating treatment at 120° C. for 3 minutes together with the laminated film in a hot-air dryer. After the heating treatment, 400 pieces of the semiconductor chips were picked up under the following picking-up conditions and the success rate of picking-up (%; success rate) was calculated to evaluate a picking-up property. The evaluation results of the picking-up property are shown as a success rate (%) in the column of “picking-up success rate (%)” in Table 1. Therefore, the picking-up property becomes better as the success rate increases.

### (Dicing Conditions)

Dicing apparatus: product name “DFD-6361” manufactured by DISCO Corporation
Dicing ring: “2-8-1” (manufactured by DISCO Corporation)

Dicing speed: 80 mm/sec
Dicing blade:

Z1; “2050HEDD” (manufactured by DISCO Corporation)

Z2; “2050HEBB” (manufactured by DISCO Corporation)
Dicing blade rotation speed:

Z1; 40,000 rpm

Z2; 40,000 rpm
Blade height:

Z1; 0.170 mm

Z2; 0.085 mm
Cutting method: A mode/step cutting
Wafer chip size: 10.0 mm square

### (Picking-Up Conditions)

Used needle: total length 10 mm, diameter 0.7 mm, acute angle 15 deg, end R 350 μm
Number of needles: 9 needles
Needle pushing-up amount: 200 μm
Needle pushing-up rate: 5 mm/sec
Collet holding time: 200 msec
Expanding: 3 mm

### (Evaluation Method of Fouling Preventive Property)

With regard to each of the pressure-sensitive adhesive sheets with a die-adhering layer, the pressure-sensitive adhesive sheet before pasted to the die-adhering layer was press-bonded to a semiconductor wafer having a diameter of 8 inch using a roller of a 2 kg load. After the press-bonding, the sheet was allowed to stand at a temperature of 23° C. for 1 hour and after standing, was subjected to a heating treatment at a temperature of 120° C. for 3 minutes using a hot-air dryer. After the heating treatment, the pressure-sensitive adhesive sheet was peeled from the semiconductor wafer under conditions of a temperature of 23° C. and a humidity of 60% RH under conditions of a drawing rate of 300 mm/min and a peeling angle of 180°. The surface of the semiconductor wafer after the peeling of the pressure-sensitive adhesive sheet was visually observed and the fouling preventive property was evaluated according to the following evaluation standard. This method was used as a substitute evaluation of the fouling protective property. In this regard, the evaluation results of the fouling preventive property are shown in the column of “Fouling preventive property” in Table 1.

### (Evaluation Standard of Fouling Preventive Property)

Absence of fouling: no transcription (remaining) of the pressure-sensitive adhesive was visually confirmed on the semiconductor wafer surface after peeling of the pressure-sensitive adhesive sheet.

Presence of fouling: transcription (remaining) of the pressure-sensitive adhesive was visually confirmed on the semiconductor wafer surface after peeling of the pressure-sensitive adhesive sheet.

From Table 1, it has been confirmed that the pressure-sensitive adhesive sheets fitted with a die-adhering layer (laminated films) according to Examples 1 to 4 satisfied the characteristics in both of the picking-up property and the fouling preventive property required in the semiconductor wafer processing steps. Namely, it has been confirmed that the adherend (cut-processed chip) can be easily peeled off without occurrence of fouling by heating when the pressure-sensitive adhesive sheets fitted with a die-adhering layer (laminated films) according to Examples 1 to 4 are used.

On the other hand, the laminated film according to Comparative Example 1 does not contain any water-supporting agent and thus the film exhibits a low picking-up property and does not satisfy the characteristics required in the semiconductor wafer processing steps. Moreover, the laminated film according to Comparative Example 2 has a pressure-sensitive adhesive layer containing silica gel supporting no water or almost no water (dried silica gel or dry silica gel) instead of the water-supporting body and thus the film exhibits a low picking-up property and does not satisfy the characteristics required in the semiconductor wafer processing steps. Furthermore, the laminated film according to Comparative Example 3 has a gel fraction of the pressure-sensitive adhesive layer of less than 90% by weight and fouling of the die-adhering layer was observed.

The laminated film of the invention can be suitably used as a pressure-sensitive adhesive sheet fitted with a die-adhering layer for use in the production of semiconductor devices such as semiconductor chips. According to the laminated film of the invention, after the cut-processing of the semiconductor wafer, the film can be easily peeled off with suppressing or preventing occurrence of fouling. Accordingly, it becomes possible to produce semiconductor devices and thus electronic parts and the like with ease and with an excellent productivity.

While the present invention has been described in detail and with reference to specific embodiments thereof, it will be apparent to one skilled in the art that various changes and modifications can be made therein without departing from the scope thereof.

This application is based on Japanese patent application No. 2009-110576 filed Apr. 30, 2009, the entire contents thereof being hereby incorporated by reference.

What is claimed is:

1. A laminated film which comprises a pressure-sensitive adhesive sheet comprising a pressure-sensitive adhesive layer, and a die-adhering layer laminated on the pressure-sensitive adhesive layer of the pressure-sensitive adhesive sheet, the laminated film being for use in a production step of a semiconductor device,
wherein the pressure-sensitive adhesive layer of the pressure-sensitive adhesive sheet contains a water-supporting body, and the pressure-sensitive adhesive layer has a gel fraction of 90% by weight or more.

2. The laminated film according to claim 1, wherein the pressure-sensitive adhesive layer is a pressure-sensitive adhesive layer containing as a base polymer an acrylic polymer composed of an acrylic acid alkyl ester represented by CH₂═CHCOOR (where R is an alkyl group having 6 to 10 carbon atoms) as a main monomer component, and the ratio of the acrylic acid alkyl ester represented by the above formula is 50 to 99% by mol based on the total amount of monomer components.

3. The laminated film according to claim 1, wherein a support in the water-supporting body is at least one water-supportable body selected from zeolites, molecular sieves, silica gel, and water-swelling gel-forming agents.

4. The laminated film according to claim 1, wherein the pressure-sensitive adhesive layer has a pressure-sensitive adhesive force (peeling angle: 15°, drawing rate: 300 mm/min) at 23° C. of 1 N/10 mm width to 10 N/10 mm width when the laminated film is press-bonded (pressure: 1.47×10⁵ Pa, time: 1 minute) to a semiconductor wafer having a thickness of 0.6 mm by a heat lamination method at 40° C. in such a form that the die-adhering layer comes into contact with a surface of the semiconductor wafer and subsequently allowed to stand under an atmosphere of 23° C. for 30 minutes, and
the pressure-sensitive adhesive layer has a pressure-sensitive adhesive force (peeling angle: 15°, drawing rate: 300 mm/min) at 23° C. of 5 N/10 mm width or less when the laminated film is press-bonded (pressure: 1.47×10⁵ Pa, time: 1 minute) to a semiconductor wafer having a thickness of 0.6 mm by a heat lamination method at 40° C. in such a form that the die-adhering layer comes into contact with a surface of the semiconductor wafer, subsequently allowed to stand under an atmosphere of 120° C. for 3 minutes, and thereafter allowed to stand under an atmosphere of 23° C. for 30 minutes.

5. A process for producing a semiconductor device, in which a laminated film which comprises a pressure-sensitive adhesive sheet comprising a pressure-sensitive adhesive layer, and a die-adhering layer laminated on the pressure-sensitive adhesive layer of the pressure-sensitive adhesive sheet is used, the process comprises steps of:
attaching a semiconductor wafer to the die-adhering layer of the laminated film according to claim 1,
subjecting the semiconductor wafer having the laminated film attached thereto to a cut-processing treatment,
peeling semiconductor chips formed by the cut-processing treatment from the pressure-sensitive adhesive layer together with the die-adhering layer, and
adhering the semiconductor chip fitted with the die-adhering layer to an adherend.
